(19) United States
(12) Patent Application Publication
(10) Pub. No.: US 2025/0293085 A1
(43) Pub. Date: Sep. 18, 2025

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Wei-Tao TSAI, Tainan City (TW); Kai-Yun YANG, Tainan (TW); Chun-Hao CHOU, Tainan City (TW)

(21) Appl. No.: 18/741,126

(22) Filed: Jun. 12, 2024

Related U.S. Application Data
(60) Provisional application No. 63/564,156, filed on Mar. 12, 2024.

(51) Int. Cl. H01L 21/768; H01L 21/308; H01L 21/311; H01L 23/522; H01L 23/528; H01L 23/532

(52) U.S. Cl. CPC H01L 21/76831; H01L 21/3086; H01L 21/31122; H01L 21/31144; H01L 21/76814; H01L 21/76832; H01L 21/76877; H01L 23/5226; H01L 23/528; H01L 23/5329

(57) ABSTRACT

An elongated conductive structure is included through a device layer of a semiconductor die included in a semiconductor die package. The elongated conductive structure connects to metallization layers in the interconnect structures on opposing sides of the device layer. To prevent, minimize, and/or reduce current leakage from the elongated conductive structure, one or more liners may be included between the elongated conductive structure and the device layer. The one or more liners include a high dielectric constant (high-k) dielectric liner. The high-k dielectric liner provides increased electrical isolation compared to other types of dielectric liners. In this way, the high-k dielectric liner enables increased electrical isolation, in addition to providing surface passivation and/or metal diffusion blocking, to be achieved.

### CROSS-REFERENCE TO RELATED APPLICATION

This patent application claims priority to U.S. Provisional Patent Application No. 63/564,156, filed on Mar. 12, 2024, and entitled “SEMICONDUCTOR DIE PACKAGES AND METHODS OF FORMATION.” The disclosure of the prior application is considered part of and is incorporated by reference into this patent application.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor die package described herein.

FIGS. 2A-2F are diagrams of examples of configurations and/or arrangements of liners that may be included between an elongated conductive structure and a device layer of a semiconductor die described herein.

FIGS. 3A-3H are diagrams of an example implementation of forming a semiconductor die described herein.

FIGS. 4A and 4B are diagrams of an example implementation of forming a semiconductor die package described herein.

FIGS. 5A-5H are diagrams of an example implementation of forming an elongated conductive structure described herein.

FIGS. 6A-6C are diagrams of an example implementation of forming an elongated conductive structure described herein.

FIGS. 7A-7F are diagrams of an example implementation of forming an elongated conductive structure described herein.

FIG. 8 is a diagram of an example semiconductor die package described herein.

FIG. 9 is a diagram of an example semiconductor die package described herein.

FIG. 10 is a diagram of an example semiconductor die package described herein.

FIG. 11 is a diagram of an example semiconductor die package described herein.

FIGS. 12A-12J are diagrams of an example implementation of forming an interconnect structure of a semiconductor die described herein.

FIG. 13 is a flowchart of an example process associated with forming a semiconductor die package described herein.

FIG. 14 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die in a semiconductor die package may be connected to interconnect structures on both sides of the semiconductor die. For example, a first interconnect structure may be included on a first side (e.g., a front side) of the semiconductor die, and a second interconnect structure may be included on a second side (e.g., a back side) of the semiconductor die opposing the first die. In some cases, the first interconnect structure may be used for routing signals throughout the semiconductor die, and the second interconnect structure may be used for providing power to the integrated circuit devices of the semiconductor die. Additionally and/or alternatively, one of the first or second interconnect structures may be bonded to another semiconductor die and may be used for inter-die communication, and the other interconnect structure may be connected to the connector of the semiconductor die package for making external connections.

To enable signals and/or power to be routed between the first and second interconnect structures, one or more elongated conductive structures may be included through a device layer (e.g., a semiconductor layer or semiconductor substrate) in which the integrated circuit devices are included. The elongated conductive structure(s) (sometimes referred to as through silicon vias or through substrate vias (TSVs)) connect with one or more metallization layers in the first and second interconnect structures, and may be formed of electrically conductive metals such as copper (Cu) to achieve a low electrical resistance between the metallization layers in the first and second interconnect structures through the elongated conductive structure(s).

Current leakage can occur from an elongated conductive structure (e.g., a TSV) in a semiconductor die package into a device layer of a semiconductor die included in the semiconductor die package because of the use of electrically conductive metals used in the elongated conductive structure. The current leakage from the elongated conductive structure can limit placement of integrated circuit devices near the elongated conductive structure in the device layer, resulting in an inability to decrease the pitch or distance between the elongated conductive structure and the integrated circuit devices. This may result in reduced integrated circuit density in the semiconductor die, which may in turn result in longer signal propagation distances, reduced power efficiency, and/or slower integrated circuit operation speeds, among other examples.

In some implementations described herein, an elongated conductive structure (e.g., a TSV) is included through a device layer of a semiconductor die included in a semiconductor die package. The elongated conductive structure connects to metallization layers in the interconnect structures on opposing sides of the device layer. To prevent, minimize, and/or reduce current leakage from the elongated conductive structure, one or more liners may be included between the elongated conductive structure and the device layer. The one or more liners include a high dielectric constant (high-k) dielectric liner. The high-k dielectric liner may include a high-k oxide dielectric material having a dielectric constant that is greater than or approximately equal to the dielectric constant of silicon nitride (Si₃N₄—dielectric constant of approximately 7 to approximately 10). In some implementations, a combination of different high-k dielectric liners may be included between the elongated conductive structure and the device layer.

The high-k dielectric liner provides increased electrical isolation compared to other dielectric liners that include low dielectric constant (low-k) dielectric materials and/or nitride-based dielectric materials such as silicon nitride. The high-k dielectric liner may be included in addition to low-k dielectric liners and/or silicon nitride-based liners to achieve increased electrical isolation, in addition to providing surface passivation and/or metal diffusion blocking. In this way, the high-k dielectric liner may provide greater flexibility in placement of integrated circuit devices near the elongated conductive structure in the device layer. In particular, the reduced current leakage provided by the high-k dielectric liner may enable the pitch or distance between the elongated conductive structure and the integrated circuit devices to be decreased. This may enable increased integrated circuit density to be achieved in the semiconductor die, which may enable shorter signal propagation distances to be achieved, may enable increased power efficiency to be achieved, and/or may enable faster integrated circuit operation speeds to be achieved, among other examples.

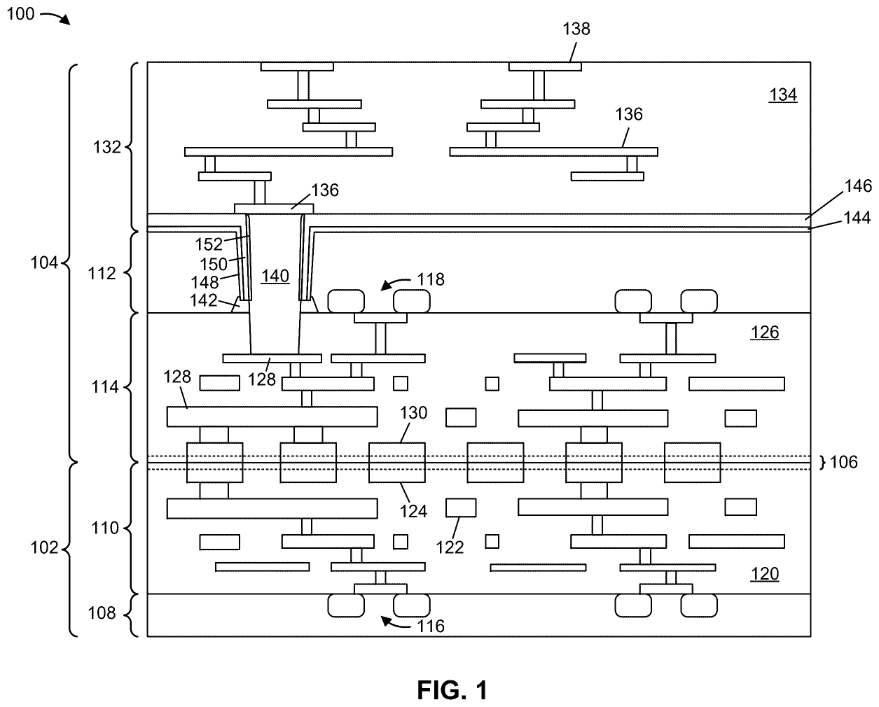

FIG. 1 is a diagram of an example semiconductor die package 100 described herein. FIG. 1 illustrates a cross-section view of the semiconductor die package 100. As shown in FIG. 1, the semiconductor die package 100 includes a semiconductor die 102 and a semiconductor die 104 bonded at a bonding interface 106 such that the semiconductor dies 102 and 104 are stacked and vertically arranged in the semiconductor die package 100. The bond between the semiconductor dies 102 and 104 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIG. 1, the semiconductor die 102 may include a device layer 108 and an interconnect structure 110 above the device layer 108. The semiconductor die 104 may include a device layer 112 and an interconnect structure 114 below the device layer 112. The bonding interface 106 may be located between the interconnect structures 110 and 114, and may include portions of each of the interconnect structures 110 and 114. The bonding interface 106 may include conductive structures of the interconnect structures 110 and 114 that are bonded together by metal-to-metal bonds, and/or dielectric layers of the interconnect structures 110 and 114 that are bonded together by dielectric-to-dielectric bonds.

The device layer 108 may correspond to a portion of a semiconductor wafer on which the semiconductor die 102 was formed, and the device layer 112 may correspond to a portion of another semiconductor wafer on which the semiconductor die 104 was formed. The device layers 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layers 108 and 112 may respectively include integrated circuit devices 116 and 118 of the semiconductor dies 102 and 104. The integrated circuit devices 116 and 118 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The interconnect structures 110 and 114 may each include conductive structures that interconnect the integrated circuit devices 116 and 118 of the device layers 108 and 112, respectively. Additionally and/or alternatively, the interconnect structures 110 and 114 may each include conductive structures that electrically connect the semiconductor dies 102 and 104.

The interconnect structure 110 of the semiconductor die 102 includes one or more dielectric layers 120 that are arranged in a direction that is approximately perpendicular to the device layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect structure 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect structure 110 includes a plurality of conductive structures 122 (e.g., electrically conductive structures) in the dielectric layer(s) 120. The conductive structures 122 are electrically coupled and/or physically coupled with one or more of the integrated circuit devices 116 in the device layer 108, and are electrically interconnected together in the interconnect structure 110. The conductive structures 122 correspond to circuit routing that enables signals and/or power to be provided to and/or from the integrated circuit devices 116. The conductive structures 122 may include a combination of conductive structures that extend primarily horizontally in the interconnect structure 110 (e.g., trenches, conductive lines) and that are interconnected by interconnects (e.g., vias) that extend primarily vertically in the interconnect structure 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect structure 110 may be arranged in a vertical manner to facilitate electrical signals and/or power to be routed between the device layer 108 and the semiconductor die 104, between integrated circuit devices 116 through the interconnect structure 110, and/or between the integrated circuit devices 116 and the integrated circuit devices 118 in the semiconductor die 104. The conductive structures 122 may be arranged in alternating layers of metallization layers (referred to as “M”-layers) and via layers (referred to as “V”-layers). Each metallization layer may include one or more conductive structures laterally arranged in the interconnect structure 110, and each via layer may include one or more interconnects that interconnect the metallization layers in the interconnect structure 110. As an example, a metal-0 (M0) layer may be located at the bottom of the interconnect structure 110 and may be coupled with the integrated circuit devices 116 in the device layer 108, a via-0 (V0) layer may be located above and coupled with the M0 layer in the interconnect structure 110, a metal-1 (M1) layer may be located above and coupled with the V0 layer in the interconnect structure 110, a via-1 (V1) layer may be located above and coupled with the M1 layer in the interconnect structure 110, a metal-2 (M2) layer may be located above and electrically coupled with the V1 layer in the interconnect structure 110, and so on. In some implementations, the interconnect structure 110 includes nine (9) stacked metallization layers (e.g., M0-M8). In other implementations, the contact layer (referred to as “CO”-layer) may be located at the bottom of the interconnect structure 110 and may be coupled with the integrated circuit devices 116 in the device layer 108, a metal-1 (M1) layer may be located above and coupled with the CO layer in the interconnect structure 110, and so on. In some implementations, the interconnect structure 110 includes another quantity of stacked metallization layers.

At the bonding interface 106, the interconnect structure 110 may include a plurality of bonding pads 124. The bonding pads 124 may be electrically coupled with the conductive structures 122 in the interconnect structure 110 by bonding vias and/or other types of conductive structures. The bonding pads 124 may each include tungsten (W), cobalt (Co), ruthenium (Ru), titanium (Ti), aluminum (Al), copper (Cu), gold (Au), and/or a combination thereof, among other examples of electrically conductive metals.

As further shown in FIG. 1, the interconnect structure 114 of the semiconductor die 104 may include a similar combination and/or arrangement of structures and/or layers as the interconnect structure 110 of the semiconductor die 102. For example, the semiconductor die 104 may include a combination of one or more dielectric layers 126 and conductive structures 128 in the dielectric layer(s) 126. Moreover, the interconnect structure 114 may include bonding pads 130 that are electrically coupled with one or more of the conductive structures 128 (e.g., by bonding vias and/or other types of conductive structures). These layers and/or structures may have a reversed vertical arrangement relative to the semiconductor die 102, which enables the semiconductor die 102 and the semiconductor die 104 to be bonded at the bonding interface 106 such that the interconnect structure 110 and the interconnect structure 114 are facing each other.

At the bonding interface 106, the bonding pads 124 of the semiconductor die 102 and the bonding pads 130 of the semiconductor die 104 are directly bonded by metal-to-metal bonds. Moreover, a dielectric layer of the one or more dielectric layers 120 of the semiconductor die 102 and a dielectric layer of the one or more dielectric layers 126 of the semiconductor die 104 are directly bonded by dielectric-to-dielectric bonds.

As further shown in FIG. 1, the semiconductor die 104 may include another interconnect structure 132. The interconnect structure 114 may be located on a first side (e.g., a front side) of the device layer 112 of the semiconductor die 104, and the interconnect structure 132 may be located on a second side (e.g., a back side) of the device layer 112 opposing the first side. The interconnect structure 114 may be configured to route signals and/or power between the semiconductor dies 102 and 104, and/or may be configured to route signals and/or power between integrated circuit devices 118 of the semiconductor die 104. The interconnect structure 132 may be configured to route signals and/or power between the semiconductor die 104 and devices external to the semiconductor die package 100. For example, the interconnect structure 132 may be configured to route signals and/or power between the semiconductor die 104 and an external high bandwidth memory (HBM) die, an external system on chip (SoC) die, an external input/output (I/O) die, and/or another type of device external to the semiconductor die package 100.

The interconnect structure 132 of the semiconductor die 104 includes one or more dielectric layers 134 (e.g., ILD layers, IMD layers, ESLs) and conductive structures 136 (e.g., trenches, metallization layers, vias, interconnects) in the dielectric layer(s) 134. The dielectric layer(s) 134 may each include an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material. The conductive structures 136 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect structure 132 further includes connection structures 138 that enable the semiconductor die package 100 to be attached to a substrate (e.g., an interposer, a printed circuit board (PCB)), another semiconductor die package, and/or to be attached to another structure. The connection structures 138 may include bonding pads and/or another type of connection structures.

As further shown in FIG. 1, the semiconductor die package 100 includes one or more elongated conductive structures 140 that extend between the interconnect structure 114 and 132 through the device layer 112 of the semiconductor die 104. An elongated conductive structure 140 may include a TSV, a metal pillar, a metal column, and/or other another type of vertically elongated conductive structure that physically connects and electrically connects with a conductive structure 128 (e.g., a metal pad) in the interconnect structure 114 at a first end, and that physically connects and electrically connects with a conductive structure 136 (e.g., a metal pad) in the interconnect structure 132. An elongated conductive structure 140 may be referred to as a TSV structure in that the elongated conductive structure 140 extends fully through a semiconductor layer (e.g., a silicon substrate) of the device layer 112 as opposed to extending fully through a dielectric layer or an insulator layer. An elongated conductive structure 140 may further extend through a shallow trench isolation (STI) region 142 that is included in the semiconductor layer of the device layer 112. An elongated conductive structure 140 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. The STI region 142 may include one or more dielectric materials such as a silicon oxide material (SiOₓ such as SiO₂), a silicon nitride material (SiₓN_{y} such Si₃N₄), and/or another suitable dielectric material.

As further shown in FIG. 1, one or more passivation layers may be included on the back side of the device layer 112 between the device layer 112 and the interconnect structure 132. The passivation layer(s) may be used to pattern the semiconductor layer of the device layer 112 for formation of an elongated conductive structure 140. The passivation layer(s) may include a high-k passivation layer 144 on the device layer 112 and/or a low-k passivation layer 146 on the high-k passivation layer 144. The high-k passivation layer 144 may include one or more high-k dielectric materials having a dielectric constant that is greater than approximately 3.9. The low-k passivation layer 146 may include one or more low-k dielectric material shaving a dielectric constant of approximately 3.9 or less.

An elongated conductive structure 140 may include a metal material that is susceptible to diffusion into the semiconductor layer of the device layer 112. Additionally and/or alternatively, an elongated conductive structure 140 may be located near one or more integrated circuit devices 118 in the device layer 112 that are susceptible to electrical interference by the elongated conductive structure 140. Accordingly, one or more liners may be included between the elongated conductive structure 140 and the semiconductor layer of the device layer 112 to provide a diffusion barrier and/or to provide electrical isolation between the elongated conductive structure 140 and the integrated circuit devices 118, among other examples.

The one or more liners include a high-k dielectric liner 148 between the semiconductor layer of the device layer 112 and the elongated conductive structure 140. In some implementations, the one or more liners further include a low-k dielectric liner 150 between the high-k dielectric liner 148 and the elongated conductive structure 140, and/or a nitride-containing dielectric liner 152 between the low-k dielectric liner 150 and the elongated conductive structure 140, among other examples. In some implementations, a plurality of low-k dielectric liners 150 are included.

The high-k dielectric liner 148 includes a high-k oxide dielectric material having a dielectric constant that is greater than or approximately equal to the dielectric constant of silicon nitride (Si₃N₄). For example, the high-k dielectric liner 148 includes a high-k oxide dielectric material having a dielectric constant that is at least approximately 7 to 10 or greater. Examples of such high-k oxide dielectric materials include an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the high-k dielectric liner 148 includes a multiple-layer thin film, where each layer includes a different high-k dielectric material.

The low-k dielectric liner 150 includes one or more low-k dielectric materials such as a silicon oxide (SiOₓ), an undoped silicate glass (USG), a boron-containing silicate glass (BSG), and/or a fluorine-containing silicate glass (FSG), among other examples. In some implementations, the low-k dielectric liner 150 includes an ELK dielectric material. The nitride-containing dielectric liner 152 may include a silicon nitride material (e.g., SiₓN_{y} such as Si₃N₄), a silicon oxynitride (SiON), and/or another suitable nitride-containing dielectric material.

The high-k dielectric material of the high-k dielectric liner 148 has a dielectric constant that is higher than the dielectric constant of the low-k dielectric liner 150 and, in some implementations, that is greater than the dielectric constant of the nitride-containing dielectric liner 152. The higher dielectric constant of the high-k dielectric liner 148 enables the high-k dielectric liner 148 to provide increased electrical isolation compared to the low-k dielectric liner 150 and/or compared to the nitride-containing dielectric liner 152. Thus, including the high-k dielectric liner 148 around the elongated conductive structure 140 enables a low amount of current leakage from the elongated conductive structure 140 to be achieved (e.g., lower relative to not including the high-k dielectric liner 148), which enables the integrated circuit devices 118 to be positioned closer to the elongated conductive structure 140. This enables the density of integrated circuit devices 118 in the device layer 112 to be increased, which may increase the performance of the semiconductor die 104 and/or may increase the power efficiency of the semiconductor die 104 (e.g., because of the shorter signal propagation distances between the integrated circuit devices 118), among other examples.

As indicated above, FIG. 1 is provided as an example. Other examples may differ from what is described with regard to FIG. 1.

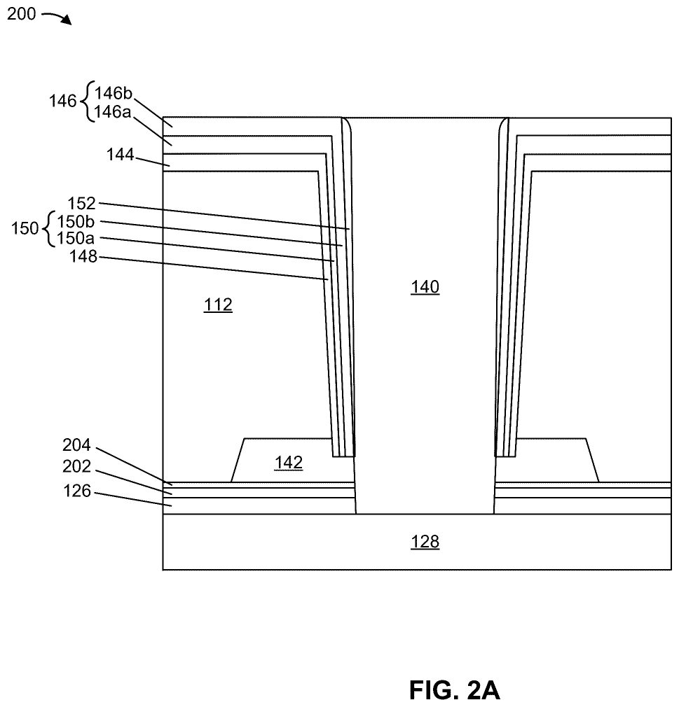

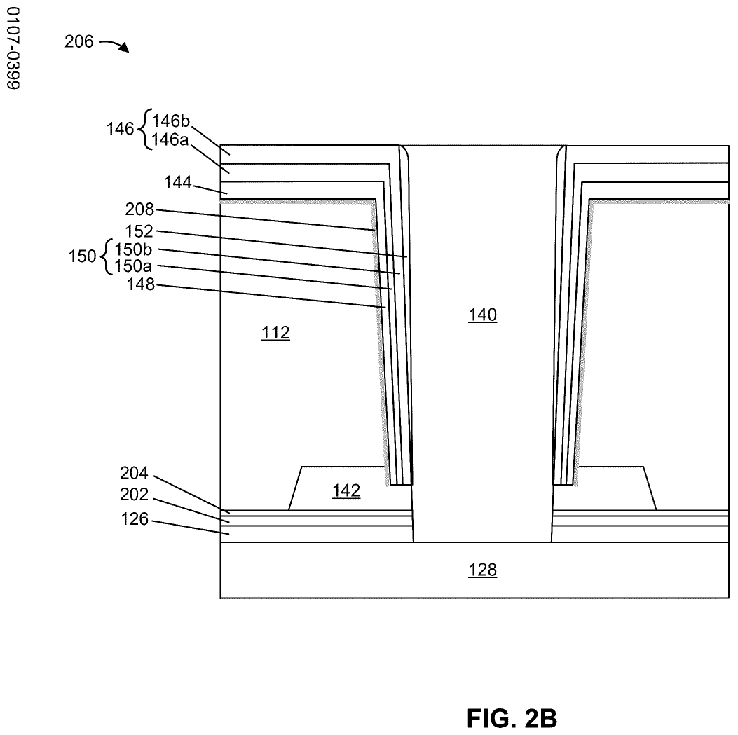

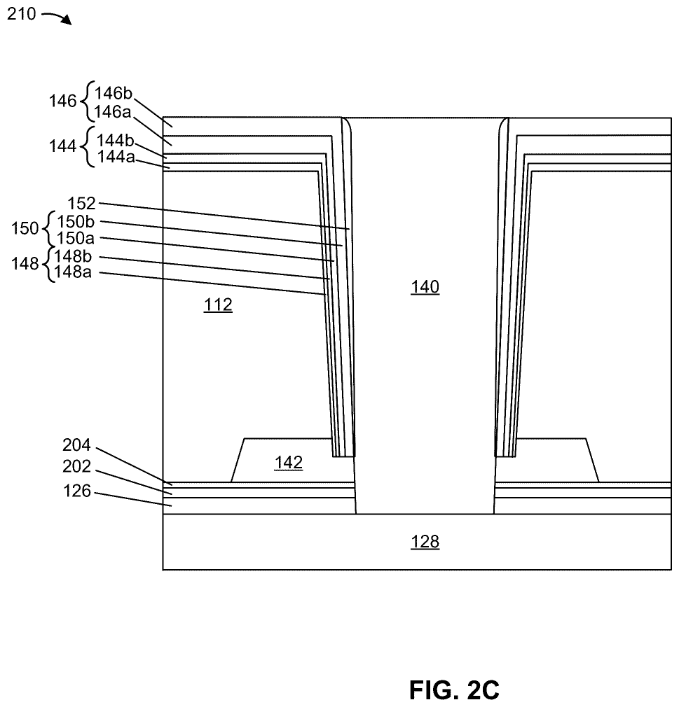

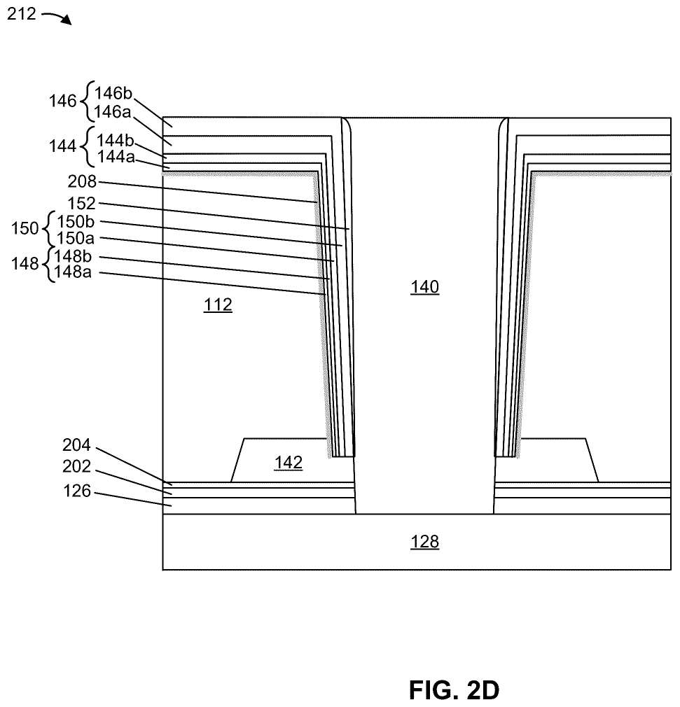

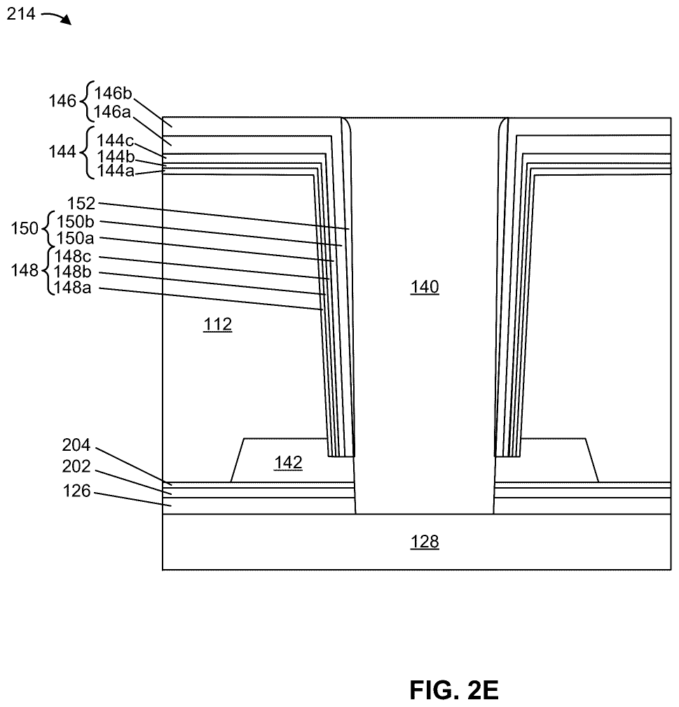

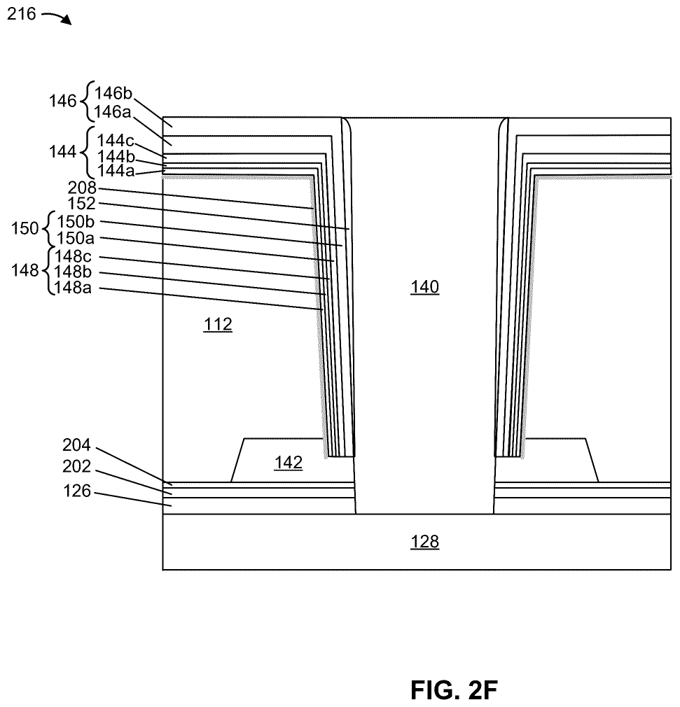

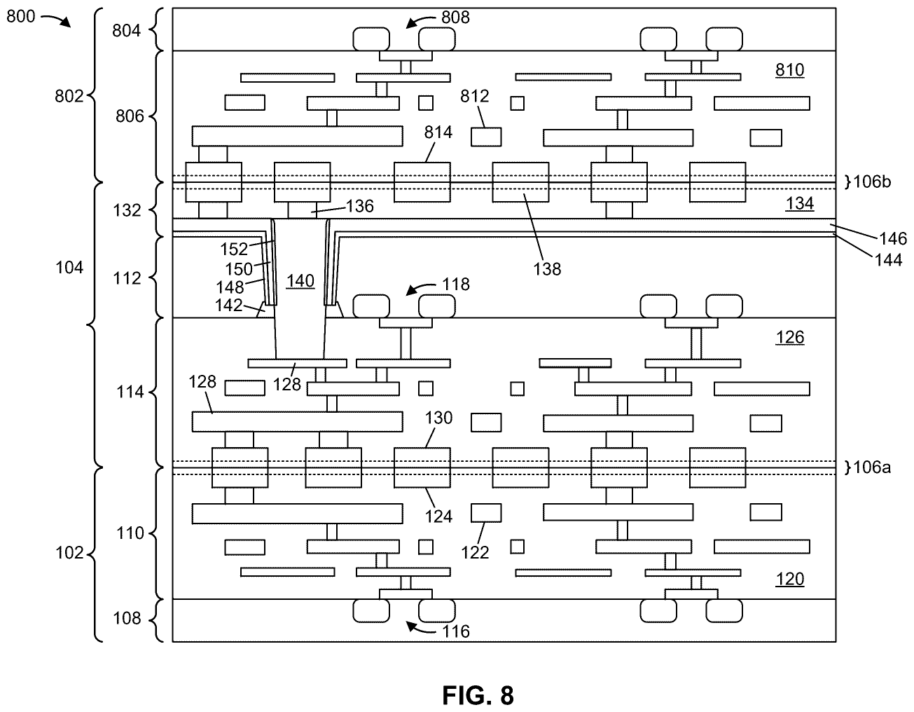

FIGS. 2A-2F are diagrams of examples of configurations and/or arrangements of liners that may be included between an elongated conductive structure 140 and a device layer of a semiconductor die described herein. While the examples of FIGS. 2A-2F are illustrated and described in connection with the device layer 112 of the semiconductor die 104, the examples of configurations and/or arrangements of liners illustrated in FIGS. 2A-2F may be implemented in the semiconductor die 102, may be implemented in a semiconductor die 802 illustrated and described in connection with FIGS. 8-10, and/or may be implemented in another semiconductor die.

FIG. 2A illustrates an example 200 in which a single-layer high-k dielectric liner 148 is included between the semiconductor layer of the device layer 112 and an elongated conductive structure 140. The high-k dielectric liner 148 includes one or more of the high-k dielectric materials described in connection with FIG. 1. In some implementations, a thickness of the high-k dielectric liner 148 is included in a range of approximately 100 angstroms to approximately 1000 angstroms. In some implementations, the thickness of the high-k dielectric liner 148 is included in a range of approximately 580 angstroms to approximately 640 angstroms. However, other values and ranges for the thickness of the high-k dielectric liner 148 are within the scope of the present disclosure. As further shown in FIG. 2A, one or more additional layers may be included between the device layer 112 and the conductive structure 128, including an ESL 202 and/or a resist protective oxide (RPO) layer 204, among other examples. The RPO layer 204 may be deposited using a low-deposition-rate technique such as plasma-enhanced chemical vapor deposition (PECVD), among other examples.

As further shown in FIG. 2A, the high-k dielectric liner 148 may extend along the sidewalls of the elongated conductive structure 140. In a top view, the high-k dielectric liner 148 wraps around the sidewalls of the elongated conductive structure 140. The high-k dielectric liner 148 may continuously and fully extend between a top and a bottom of the elongated conductive structure 140, or may partially extend from a top of the elongated conductive structure 140 and may terminate in the STI region 142 as shown in FIG. 2A.

As further shown in FIG. 2A, the low-k dielectric liner 150 includes a multiple-layer film that includes a low-k dielectric liner 150a and a low-k dielectric liner 150b. The low-k dielectric liner 150 may be formed during deposition of the low-k passivation layer 146, and therefore the low-k passivation layer 146 may also include multiple layers, including a low-k passivation layer 146a and a low-k passivation layer 146b.

In some implementations, the low-k dielectric liner 150a and the low-k dielectric liner 150b include the same dielectric material or the same material composition. In some implementations, the low-k dielectric liner 150a and the low-k dielectric liner 150b include different dielectric materials and/or different material compositions. For example, the low-k dielectric liner 150a may include USG and the low-k dielectric liner 150b may include silicon dioxide (SiO₂). In some implementations, the low-k dielectric liner 150a and the low-k dielectric liner 150b are formed using different deposition techniques. For example, the low-k dielectric liner 150a may be deposited using a chemical vapor deposition (CVD) technique and the low-k dielectric liner 150b may be deposited using a plasma-enhanced atomic layer deposition (ALD) (PEALD) technique.

In some implementations, a thickness of the low-k dielectric liner 150 (a combined thickness of the low-k dielectric liner 150a and the low-k dielectric liner 150b) is greater than a thickness of the high-k dielectric liner 148. For example, the thickness of the low-k dielectric liner 150 may be included in a range of approximately 1500 angstroms to approximately 2000 angstroms. However, other values and ranges for the thickness of the low-k dielectric liner 150 are within the scope of the present disclosure. In some implementations, a thickness of the low-k dielectric liner 150a is included in a range of approximately 400 angstroms to approximately 600 angstroms. However, other values and ranges for the thickness of the low-k dielectric liner 150a are within the scope of the present disclosure. In some implementations, the thickness of the low-k dielectric liner 150b is included in a range of approximately 1250 angstroms to approximately 1750 angstroms. However, other values and ranges for the thickness of the low-k dielectric liner 150b are within the scope of the present disclosure.

As further shown in FIG. 2A, the nitride-containing dielectric liner 152 may have a tapered cross-sectional profile. At the top of the elongated conductive structure 140, the thickness of the nitride-containing dielectric liner 152 may be included in a range of approximately 1800 angstroms to approximately 2200 angstroms, and the thickness of the nitride-containing dielectric liner 152 may be reduced as a function of depth in the device layer 112. However, other values and ranges for the thickness of the nitride-containing dielectric liner 152 are within the scope of the present disclosure. The tapered cross-sectional profile may result from the type of deposition process that is used to deposit the nitride-containing dielectric layer 152. For example, a deposition process such as a plasma-enhanced chemical vapor deposition (PECVD) process may be used to form the nitride-containing dielectric layer 152, and the PECVD process may have poor step coverage which results in the nitride-containing dielectric layer 152 being thicker at the top of the recess than at the bottom of the recess. This may result in an overhang of the material of the nitride-containing dielectric layer 152.

The nitride-containing dielectric liner 152 on the top surface of the back side of the semiconductor layer of the device layer 112 may be included as an etch stop layer for formation of the recess in which the elongated conductive structure 140 is formed. In some implementations, the recess is formed in a two-step etch process, and the nitride-containing dielectric liner 152 protects the sidewalls of the recess from lateral expansion during a second part of the two-step etch process. The overhang of the material of the nitride-containing dielectric layer 152 resulting from the tapered cross-sectional profile may act as a self-aligned etch layer that protects the sidewalls of the recess from being etched. In some implementations, the nitride-containing dielectric layer 152 may be mostly removed during etching of the recess, where a small amount of the nitride-containing dielectric liner 152 remains on the sidewalls of the recess as a liner.

FIG. 2B illustrates an example 206, which is similar to the example 200 in FIG. 2A except that an additional low-k dielectric liner 208 is included between the semiconductor layer of the device layer 112 and the high-k dielectric liner 148. The low-k dielectric liner 208 may be included as a passivation layer to passivate defects in the semiconductor layer that may have been formed as a result of formation of a recess in which the elongated conductive structure 140 was formed. Additionally and/or alternatively, the low-k dielectric liner 208 may be included as an adhesion layer to tune the interface between the semiconductor layer and the high-k dielectric liner 148. In some implementations, the low-k dielectric liner 208 is also included on the top surface of the semiconductor layer of the device layer 112 to prevent, minimize, and/or reduce surface contamination of the top surface of the semiconductor layer.

The low-k dielectric liner 208 may include a low-k oxide dielectric such as silicon dioxide (SiO₂) and/or USG, among other examples. A thickness of the low-k dielectric liner 208 may be less than the thickness of the high-k dielectric liner 148. For example, the thickness of the low-k dielectric liner 208 may be included in a range of approximately 5 angstroms to approximately 20 angstroms. As another example, the thickness of the low-k dielectric liner 208 may be included in a range of approximately 15 angstroms to approximately 20 angstroms. However, other values and ranges for the thickness of the low-k dielectric liner 208 are within the scope of the present disclosure.

FIG. 2C illustrates an example 210, which is similar to the example 200 in FIG. 2A except that the high-k dielectric liner 148 includes a multiple-layer thin film. For example, the high-k dielectric liner 148 includes a high-k dielectric liner 148a on the semiconductor layer of the device layer 112, and a high-k dielectric liner 148b on the high-k dielectric liner 148a. The high-k dielectric liner 148a and the high-k dielectric liner 148b may include different high-k dielectric materials to tune or optimize the electrical isolation for the elongated conductive structure 140. For example, the high-k dielectric liner 148a may include hafnium oxide (HfO₂) and the high-k dielectric liner 148b may include tantalum oxide (Ta₂O₅). As another example, the high-k dielectric liner 148a may include aluminum oxide (Al₂O₃) and the high-k dielectric liner 148b may include tantalum oxide (Ta₂O₅).

Additionally and/or alternatively, the respective thicknesses of the high-k dielectric liner 148a and the high-k dielectric liner 148b may be approximately the same or may be different thicknesses. For example, the thickness of the high-k dielectric liner 148b may be greater than the thickness of the high-k dielectric liner 148a. As another example, the thickness of the high-k dielectric liner 148a may be greater than the thickness of the high-k dielectric liner 148b. In some implementations, the thickness of the high-k dielectric liner 148a is included in a range of approximately 50 angstroms to approximately 120 angstroms, and the thickness of the high-k dielectric liner 148b is included in a range of approximately 500 angstroms to approximately 550 angstroms. However, other values and ranges for the respective thicknesses of the high-k dielectric liner 148a and the high-k dielectric liner 148b are within the scope of the present disclosure.

FIG. 2D illustrates an example 212, which is similar to the example 210 in FIG. 2C except that an additional low-k dielectric liner 208 is included between the semiconductor layer of the device layer 112 and the high-k dielectric liner 148a.

FIG. 2E illustrates an example 214, which is similar to the example 200 in FIG. 2A except that the high-k dielectric liner 148 includes a multiple-layer thin film. For example, the high-k dielectric liner 148 includes a high-k dielectric liner 148a on the semiconductor layer of the device layer 112, a high-k dielectric liner 148b on the high-k dielectric liner 148a, and a high-k dielectric liner 148c on the high-k dielectric liner 148b. The high-k dielectric liners 148a, 148b, and 148c may each include different high-k dielectric materials to further tune or optimize the electrical isolation for the elongated conductive structure 140. As an example, the high-k dielectric liner 148a may include aluminum oxide (Al₂O₃), the high-k dielectric liner 148b may include hafnium oxide (HfO₂), and the high-k dielectric liner 148c may include tantalum oxide (Ta₂O₅). Other combinations of high-k dielectric materials for the high-k dielectric liners 148a, 148b, and 148c are within the scope of the present disclosure. Alternatively, two or more of the high-k dielectric liners 148a, 148b, and/or 148c may include the same high-k dielectric material.

Additionally and/or alternatively, the respective thicknesses of the high-k dielectric liners 148a, 148b, and 148c may be approximately the same or may be different thicknesses. For example, the thickness of the high-k dielectric liner 148b may be greater than the thickness of the high-k dielectric liner 148a, and the thickness of the high-k dielectric liner 148c may be greater than the thickness of the high-k dielectric liner 148b. As another example, the thickness of the high-k dielectric liner 148a may be greater than the thickness of the high-k dielectric liner 148b, the thickness of the high-k dielectric liner 148a may be greater than the thickness of the high-k dielectric liner 148c, and/or the thickness of the high-k dielectric liner 148b may be greater than the thickness of the high-k dielectric liner 148c. In some implementations, the thickness of the high-k dielectric liner 148a is included in a range of approximately 40 angstroms to approximately 60 angstroms, the thickness of the high-k dielectric liner 148b is included in a range of approximately 60 angstroms to approximately 80 angstroms, and the thickness of the high-k dielectric liner 148c is included in a range of approximately 500 angstroms to approximately 550 angstroms. However, other values and ranges for the respective thicknesses of the high-k dielectric liners 148a, 148b, and 148c are within the scope of the present disclosure.

FIG. 2F illustrates an example 216, which is similar to the example 214 in FIG. 2E except that an additional low-k dielectric liner 208 is included between the semiconductor layer of the device layer 112 and the high-k dielectric liner 148a.

As indicated above, FIGS. 2A-2F are provided as examples. Other examples may differ from what is described with regard to FIGS. 2A-2F.

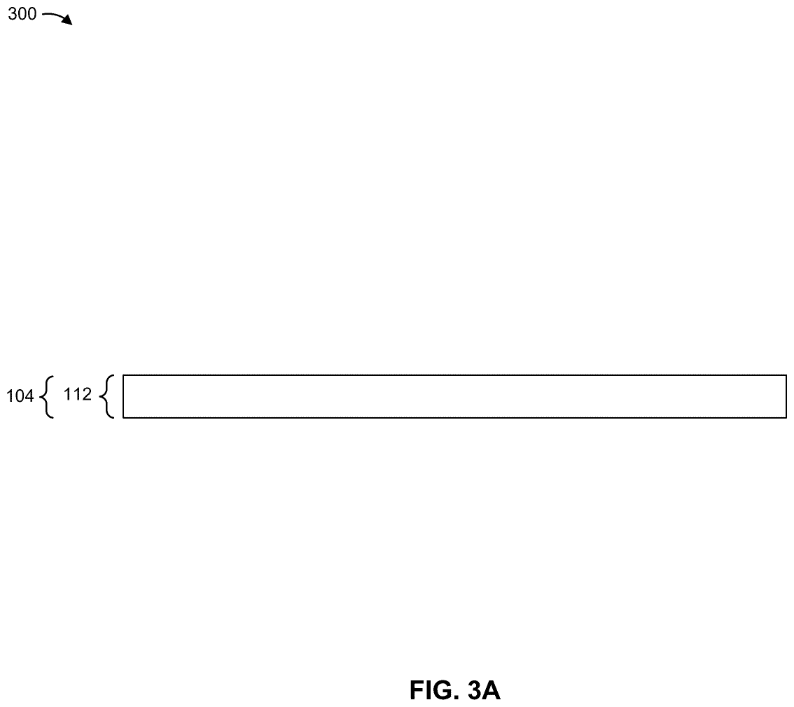

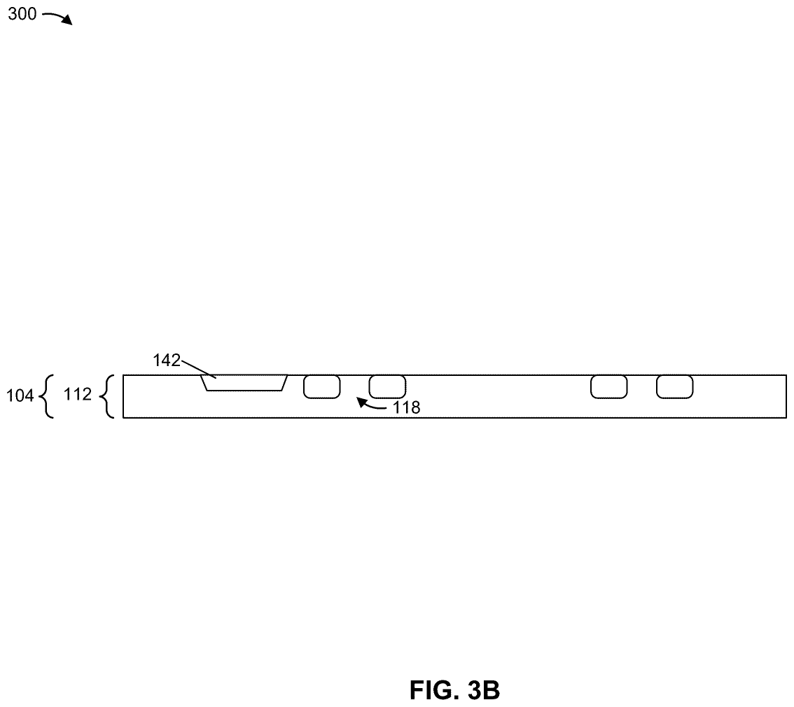

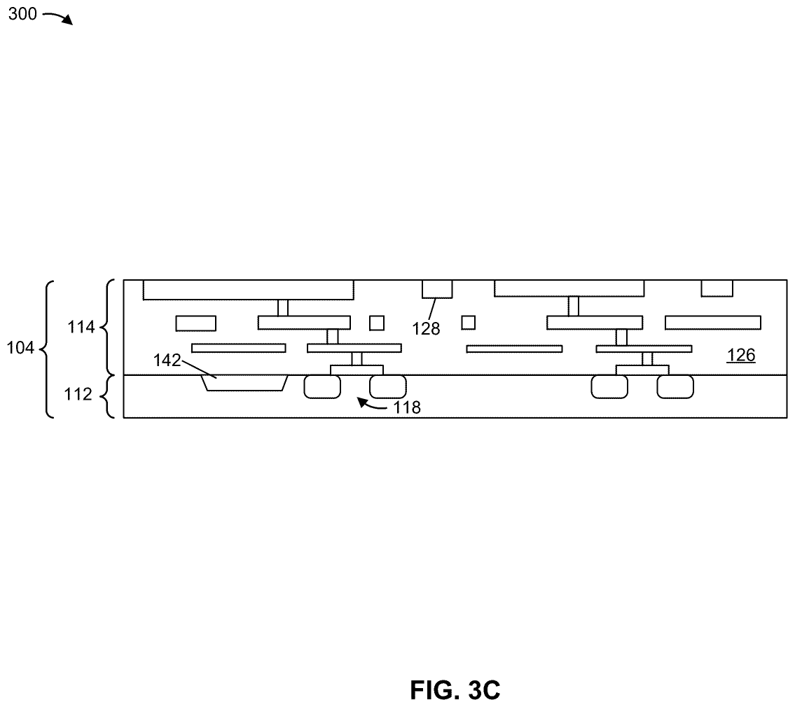

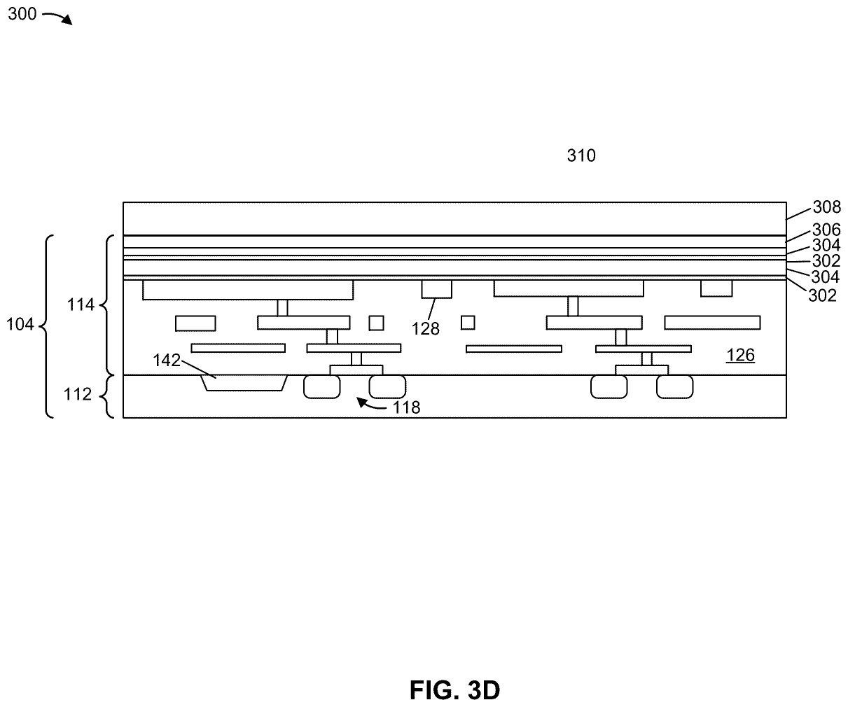

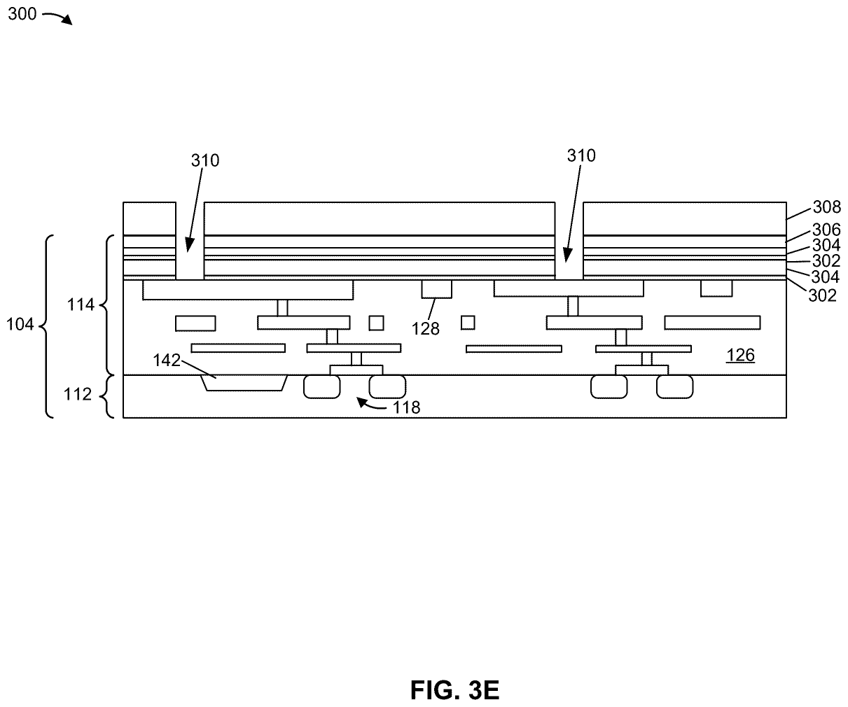

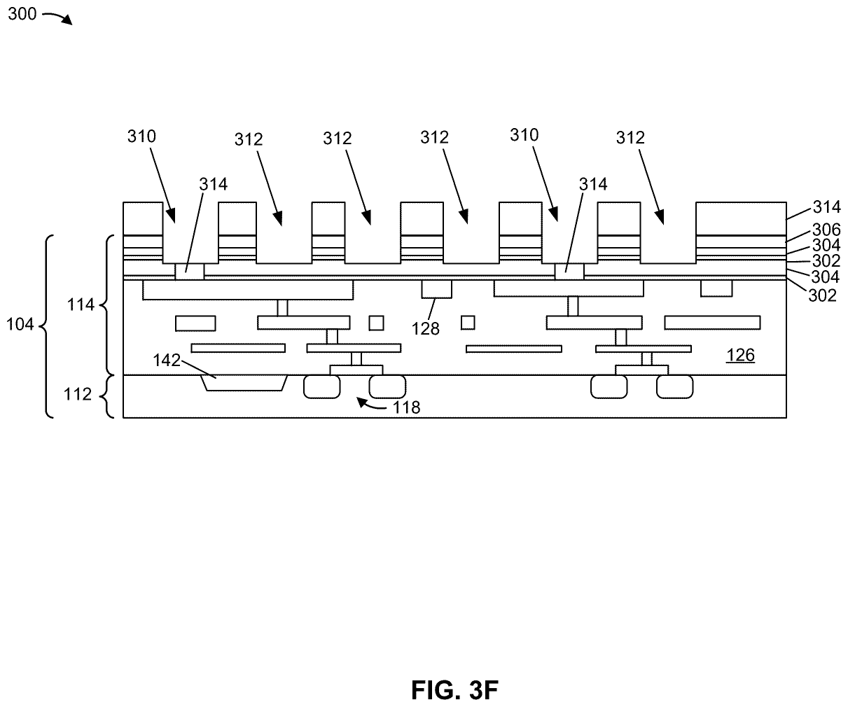

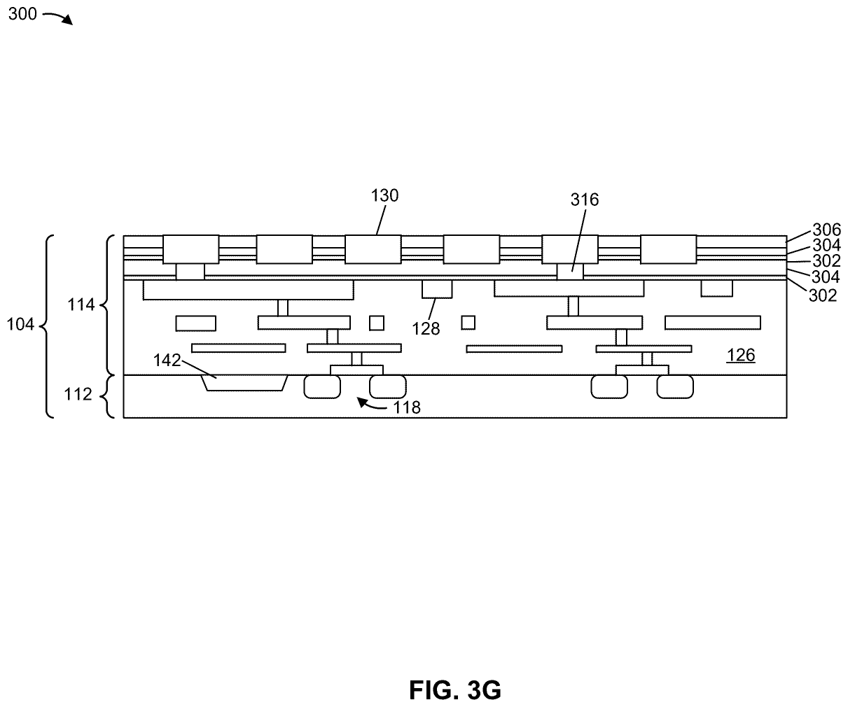

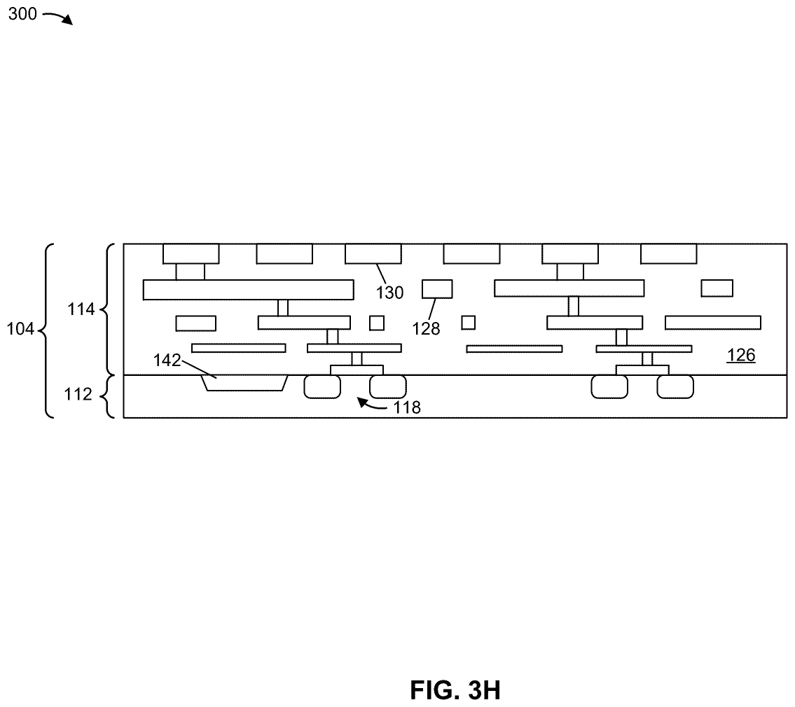

FIGS. 3A-3H are diagrams of an example implementation 300 of forming a semiconductor die described herein. In some implementations, the example implementation 300 includes an example process for forming the semiconductor die 104 or a portion thereof. In some implementations, one or more of the operations described in connection with the example implementation 300 may be performed to form another semiconductor die described herein, such as a semiconductor die 102, a semiconductor die 802 illustrated in FIGS. 8-10, and/or another semiconductor die described herein. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 200 may be performed in connection with the semiconductor layer of the device layer 112 of the semiconductor die 104. The semiconductor layer of the device layer 112 may be provided in the form of a semiconductor wafer or another type of semiconductor substrate.

As shown in FIG. 3B, the integrated circuit devices 118 may be formed in and/or on the device layer 112 of the semiconductor die 104. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer of the device layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer of the device layer 112 with one or more types of dopants (e.g., p-type dopants, n-type dopants).

As further shown in FIG. 3B, an STI region 142 may be formed in the device layer 112. The STI region 142 may be formed in a recess in the device layer 112. In some implementations, a pattern in a photoresist layer is used to etch the device layer 112 to form the recess in the device layer 112. In these implementations, a deposition tool may be used to form the photoresist layer on the device layer 112. An exposure tool may be used to expose the photoresist layer to a radiation source to pattern the photoresist layer. A developer tool may be used to develop and remove portions of the photoresist layer to expose the pattern. An etch tool may be used to etch the device layer 112 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the device layer 112 based on a pattern.

A deposition tool may be used to deposit the dielectric material of the STI region 142 in the recess using a CVD technique, an atomic layer deposition (ALD) technique, a physical vapor deposition (PVD) technique, an oxidation technique, and/or another suitable deposition technique. The dielectric material of the STI region 142 may be deposited in one or more deposition operations. In some implementations, a planarization tool may be used to perform a planarization operation (e.g., a chemical mechanical planarization (CMP) operation) to planarize the STI region 142 after the dielectric material of the STI region 142 is deposited.

As shown in FIG. 3C, the interconnect structure 114 of the second semiconductor die 104 may be formed over and/or on the device layer 112. One or more semiconductor processing tools may be used to form the interconnect structure 114 by forming one or more dielectric layers 126 and forming a plurality of conductive structures 128 in the dielectric layer(s) 126. For example, a deposition tool may be used to deposit a first layer of the dielectric layer(s) 126 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 128 in the recesses (e.g., using a CVD technique, an ALD technique, a PVD technique, an electroplating technique, and/or another type of deposition technique). At least a portion of the first layer of conductive structures 128 may be electrically connected and/or physically connected with the integrated circuit devices 118 in the device layer 112 (e.g., directly connected or connected through contacts). Similar processing operations may be performed to form additional layers of the interconnect structure 114 until a sufficient or desired arrangement of conductive structures 128 is achieved.

As shown in FIG. 3D, additional dielectric layers of the interconnect structure 114 may be formed, including an alternating arrangement of nitride dielectric layers 302 and oxide dielectric layers 304. A bonding dielectric layer 306 may be formed on the alternating arrangement of nitride dielectric layers 302 and oxide dielectric layers 304. The nitride dielectric layers 302 may include a silicon nitride material (SiₓN_{y} such as Si₃N₄) and/or another suitable nitride-containing dielectric material. The oxide dielectric layers 304 may include a silicon oxide material (SiOₓ such as SiO₂) and/or another suitable oxide-containing dielectric material. The bonding dielectric layer 306 may include a silicon oxynitride material (SiON) and/or another suitable bonding dielectric material. A deposition tool may be used to deposit the nitride dielectric layers 302, the oxide dielectric layers 304, and the bonding dielectric layer 306, each using a CVD technique, an ALD technique, a PVD technique, an oxidation technique, and/or another suitable deposition technique. In some implementations, a planarization tool may be used to perform a planarization operation (e.g., a CMP operation) to planarize the nitride dielectric layers 302, the oxide dielectric layers 304, and/or the bonding dielectric layer 306.

As further shown in FIG. 3D, a photoresist layer 308 may be formed over the bonding dielectric layer 306. The photoresist layer 308 may be formed using a deposition tool by spin-coating and/or another suitable photoresist coating technique.

As shown in FIG. 3E, via portions of recesses 310 are formed through the nitride dielectric layers 302, the oxide dielectric layers 304, and the bonding dielectric layer 306. One or more of the conductive structures 128 in the interconnect structure 114 may be exposed through the recesses 310. In some implementations, a pattern in the photoresist layer 308 is used to etch the nitride dielectric layers 302, the oxide dielectric layers 304, and the bonding dielectric layer 306 to form the recesses 310. An exposure tool may be used to expose the photoresist layer 308 to a radiation source to pattern the photoresist layer 308. A developer tool may be used to develop and remove portions of the photoresist layer 308 to expose the pattern. An etch tool may be used to etch the nitride dielectric layers 302, the oxide dielectric layers 304, and the bonding dielectric layer 306 based on the pattern to form the recesses 310. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 308 (e.g., using a chemical stripper, plasma ashing, and/or another technique).

As shown in FIG. 3F, trench portions of the recesses 310 are formed through the nitride dielectric layers 302, the oxide dielectric layers 304, and the bonding dielectric layer 306. Thus, the recesses 310 may be dual damascene recesses that have a via portion and a trench portion. Moreover, recesses 312 (e.g., single damascene recesses) may be formed in the nitride dielectric layers 302, the oxide dielectric layers 304, and the bonding dielectric layer 306.

In some implementations, a pattern in a photoresist layer 314 is used to etch the nitride dielectric layers 302, the oxide dielectric layers 304, and the bonding dielectric layer 306 to form the trench portion of the recesses 310 and to form the recesses 312. A deposition tool may be used to deposit the photoresist layer 314 on the bonding dielectric layer 306 and in the via portions of the recesses 310. An exposure tool may be used to expose the photoresist layer 314 to a radiation source to pattern the photoresist layer 314. A developer tool may be used to develop and remove portions of the photoresist layer 314 to expose the pattern. An etch tool may be used to etch the nitride dielectric layers 302, the oxide dielectric layers 304, and the bonding dielectric layer 306 based on the pattern to form the trench portion of the recesses 310 and to form the recesses 312. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 314 (e.g., using a chemical stripper, plasma ashing, and/or another technique).

As shown in FIG. 3G, bonding vias 316 may be formed in the via portions of the recesses 310, and bonding pads 130 may be formed in the trench portions of the recesses 310 and in the recesses 312. A deposition tool may be used to deposit the bonding vias 316 and the bonding pads 130 using a CVD technique, a PVD technique, an ALD technique, an electroplating technique, and/or another suitable deposition technique. The bonding vias 316 and the bonding pads 130 may be deposited in one or more deposition operations. In some implementations, a seed layer is first deposited, and the bonding vias 316 and the bonding pads 130 are deposited on the seed layer.

As shown in FIG. 3H, a planarization tool is used to perform a planarization operation (e.g., a CMP operation) to planarize the bonding pads 130 after the bonding pads 130 are deposited.

As indicated above, FIGS. 3A-3H are provided as an example. Other examples may differ from what is described with regard to FIGS. 3A-3H.

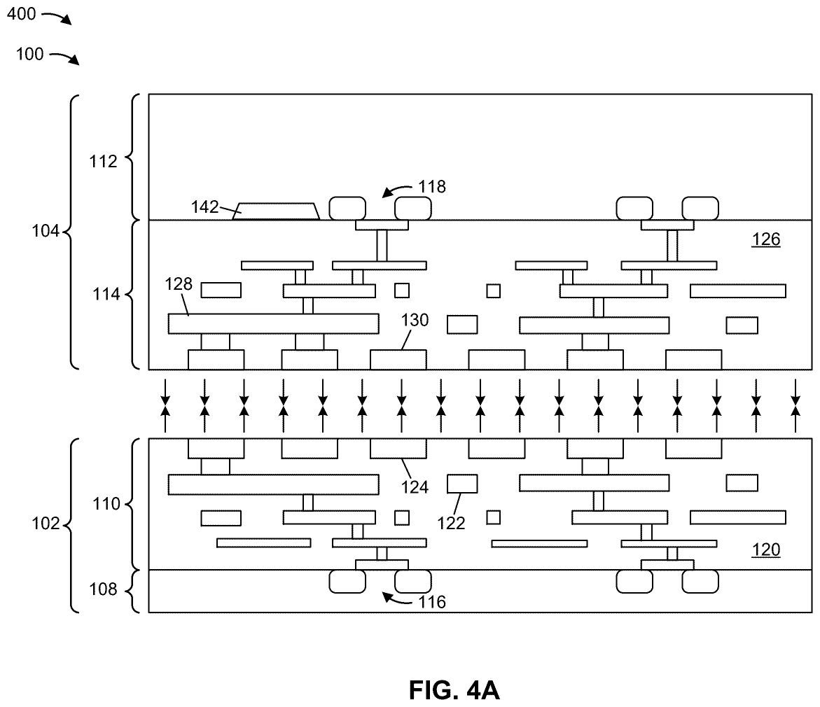

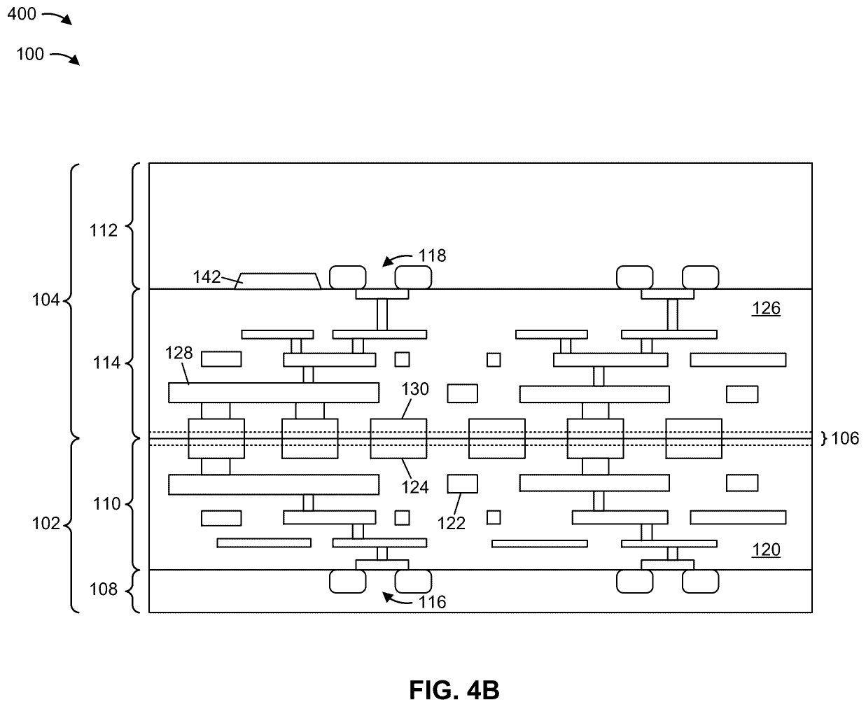

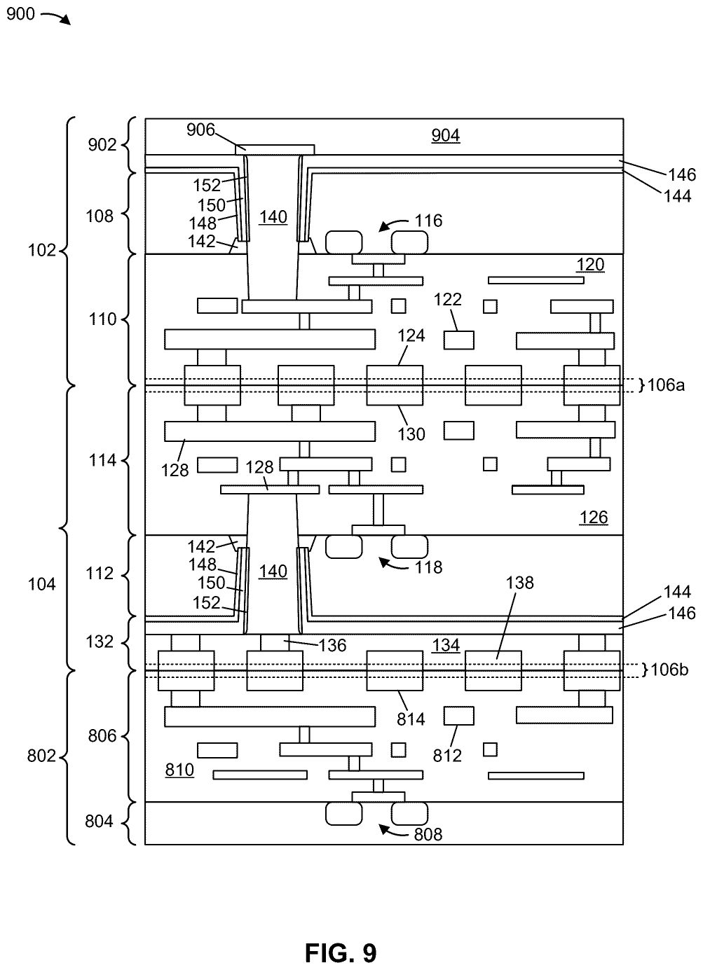

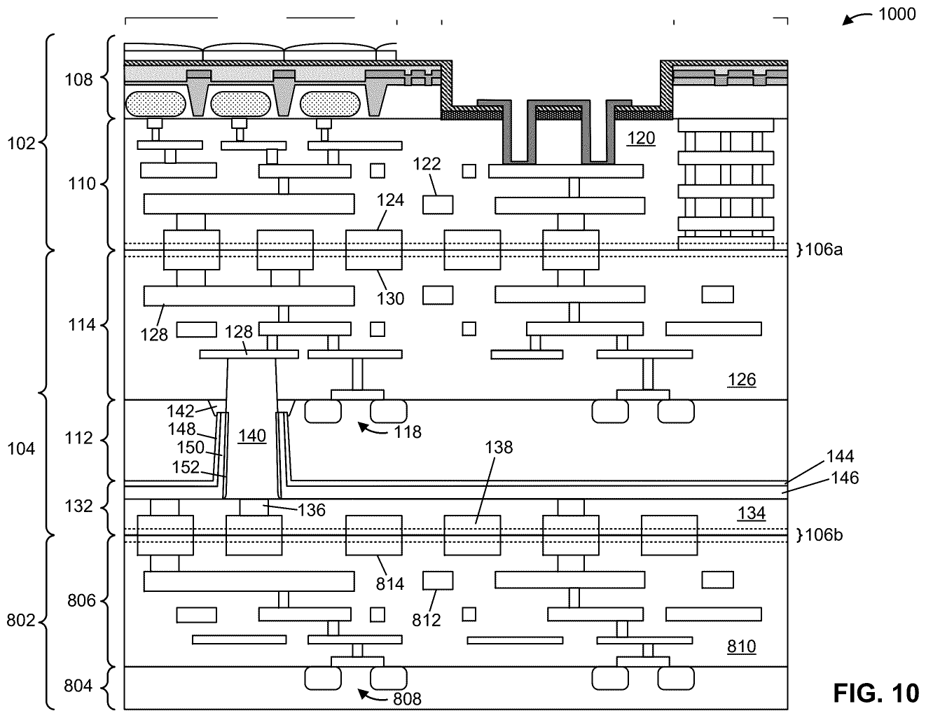

FIGS. 4A and 4B are diagrams of an example implementation 400 of forming a semiconductor die package described herein. For example, the example implementation 400 may include an example of forming a semiconductor die package 100. In some implementations, one or more of the operations described in connection with the example implementation 400 may be performed to form another semiconductor die package described herein, such as a semiconductor die package 800 illustrated in FIG. 8, a semiconductor die package 900 illustrated in FIG. 9, and/or a semiconductor die package 1000 illustrated in FIG. 10, among other examples. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

As shown in FIGS. 4A and 4B, a bonding operation is performed to bond the semiconductor die 102 and the semiconductor die 104 at the bonding interface 106 such that the semiconductor die 102 and the semiconductor die 104 are vertically arranged or stacked in the semiconductor die package 100. The semiconductor die 102 and the semiconductor die 104 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection of the bonding pads 124 of the semiconductor die 102 with the bonding pads 130 of the semiconductor die 104, and through a direct physical connection of one or more of the dielectric layers 120 of the semiconductor die 102 with one or more dielectric layers 126 of the semiconductor die 104.

As indicated above, FIGS. 4A and 4B are provided as an example. Other examples may differ from what is described with regard to FIGS. 4A and 4B.

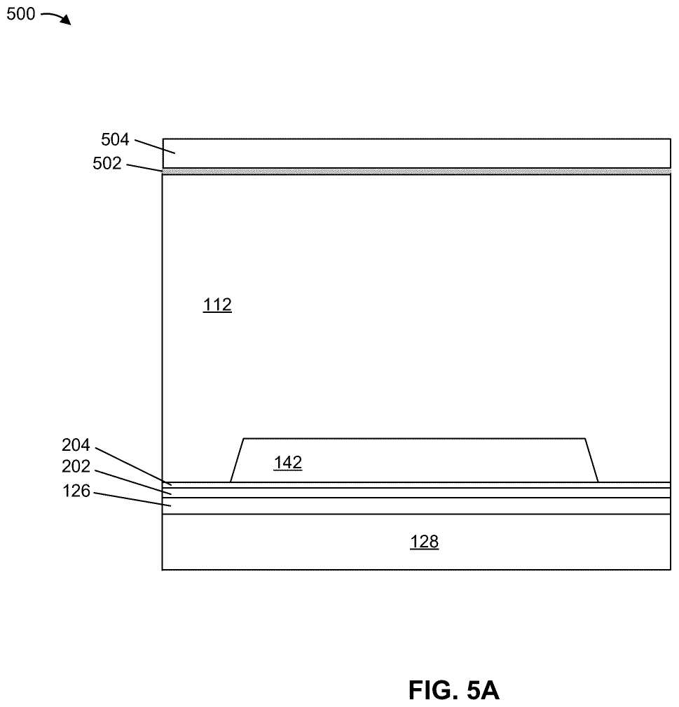

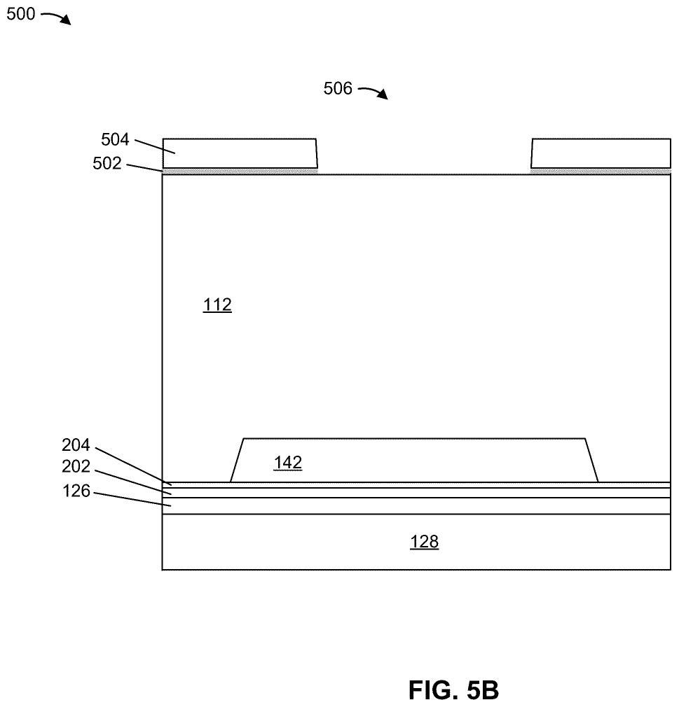

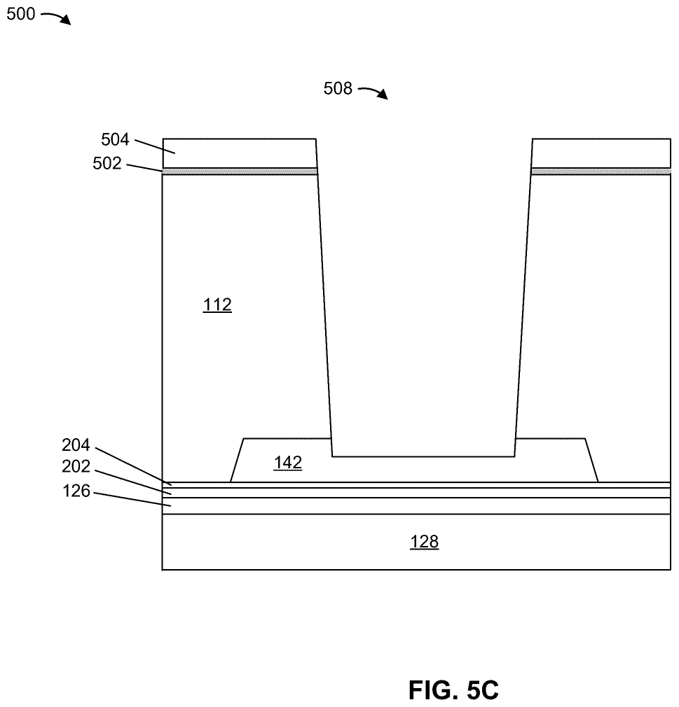

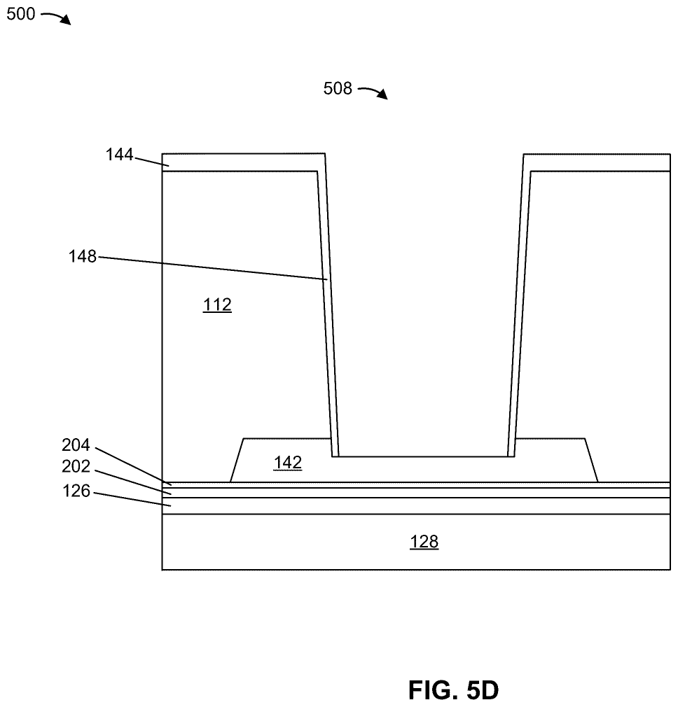

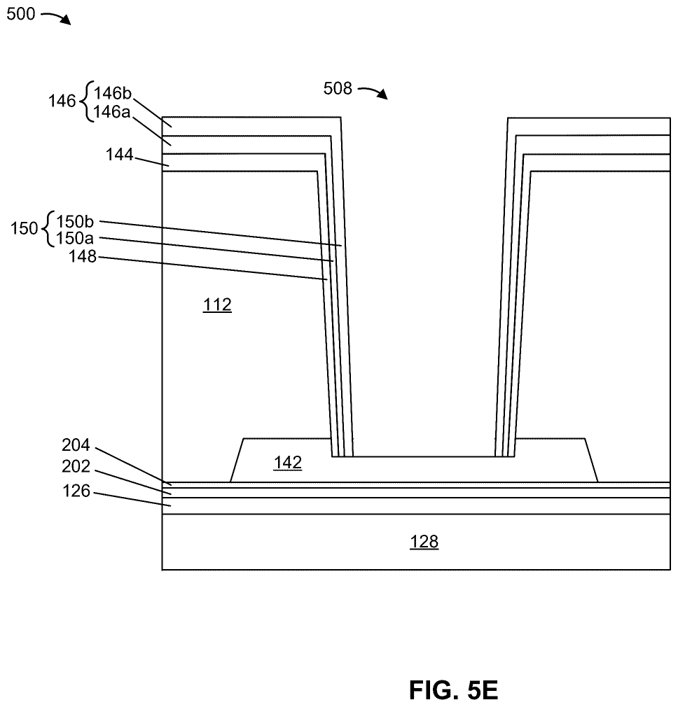

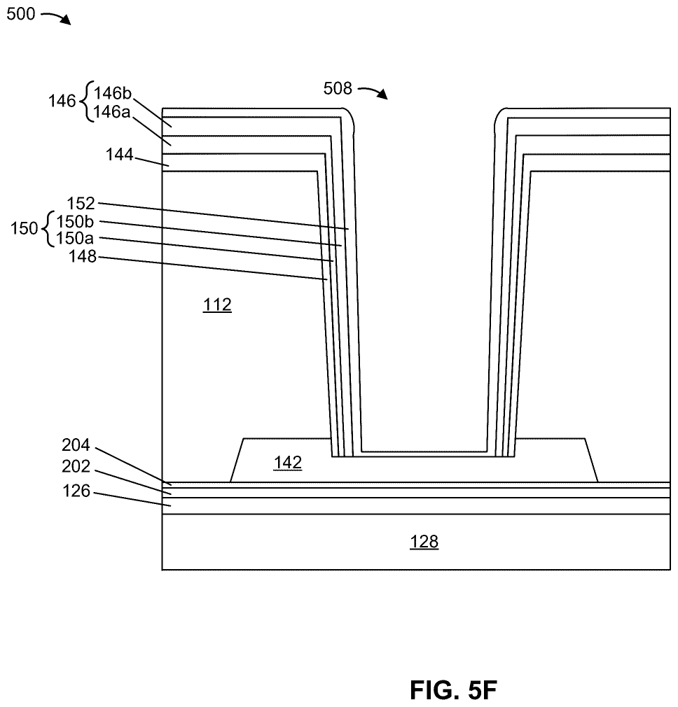

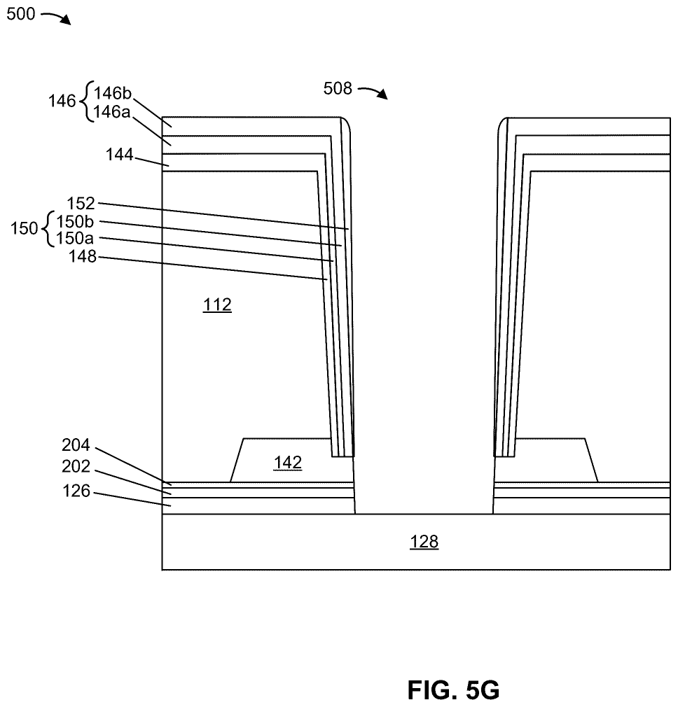

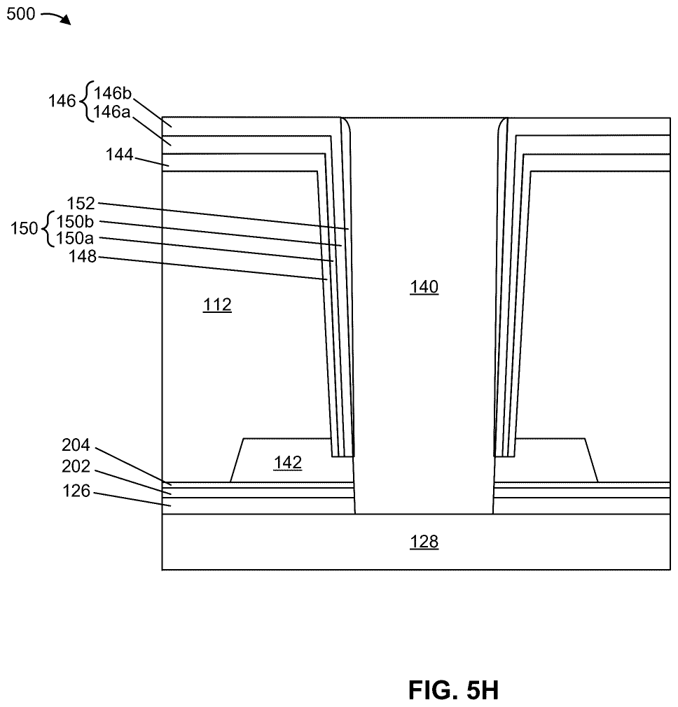

FIGS. 5A-5H are diagrams of an example implementation 500 of forming an elongated conductive structure 140 (e.g., a TSV) described herein. In some implementations, the example implementation 500 includes an example process for forming the elongated conductive structure 140 through the device layer 112 of the semiconductor die 104. In some implementations, one or more of the operations described in connection with the example implementation 500 may be performed to form an elongated conductive structure 140 through a device layer of another semiconductor die described herein, such as a device layer 108 of a semiconductor die 102, a device layer 804 of a semiconductor die 802 illustrated in FIG. 8, and/or another semiconductor die described herein. In some implementations, one or more semiconductor processing tools may be used to perform one or more of the operations described in connection with the example implementation 500, such as a deposition tool, an exposure tool, a developer tool, an etch tool, a planarization tool, a plating tool, and/or another type of semiconductor processing tool.

Turning to FIG. 5A, the semiconductor processing operations described in connection with FIGS. 5A-5H may be performed in connection with the back side of the semiconductor layer of the device layer 112 of the semiconductor die 104. The semiconductor processing operations described in connection with FIGS. 5A-5H may be performed after front side processing of the semiconductor die 104.

As shown in FIG. 5A, a low-k buffer layer 502 may be formed on the back side of the semiconductor layer of the device layer 112. A masking layer 504 (e.g., a photoresist layer) may be formed on the low-k buffer layer 502. The low-k buffer layer 502 may be included to protect the back side of the semiconductor layer of the device layer 112 from contamination. A deposition tool may be used to deposit the low-k buffer layer 502 using an ALD technique and/or another suitable conformal deposition technique. A deposition tool may be used to deposit the masking layer 504 using a spin-coating technique and/or another suitable deposition technique. In some implementations, a planarization tool is used to perform a wafer grinding operation to grind the back die of the semiconductor layer of the device layer 112 to thin the semiconductor layer prior to formation of the low-k buffer layer 502 and the masking layer 504.

As shown in FIG. 5B, a pattern 506 may be formed in the masking layer 504. To form the pattern 506, an exposure tool may be used to expose the masking layer 504 to a radiation source to pattern the masking layer 504. A developer tool may be used to develop and remove portions of the masking layer 504 to expose the pattern 506.

As shown in FIG. 5C, an etch tool may be used to perform an etch operation to etch the semiconductor layer of the device layer 112 based on the pattern 506 in the masking layer 504. The etch operation may be performed to form a recess 508 in the semiconductor layer of the device layer 112. The semiconductor layer of the device layer 112 may be etched from the back side of the device layer 112 to form the recess 508 in the back side of the semiconductor layer of the device layer 112. The recess 508 may be etched to a first depth in the semiconductor layer of the device layer 112. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

In some implementations, the etch operation stops on the STI region 142. In some implementations, the etch operation continues into a portion of the STI region 142 to ensure that the liners that are to be formed in the recess 508 provide a continuous dielectric barrier on the semiconductor layer of the device layer 112. In some implementations, the etch operation includes etching through the STI region 142 and into the dielectric layer(s) 126 of the interconnect structure 114 on the front side of the device layer 112.

As shown in FIGS. 5D-5F, the liners are formed on the sidewalls (and in some cases, on the bottom surface) of the recess 508. In implementations in which the recess 508 is formed into a portion of the STI region 142, the liners may be formed on a portion of the sidewalls of the recess 508 that correspond to the STI region 142.

As shown in FIG. 5D, the high-k passivation layer 144 may be formed on the back side of the semiconductor layer of the device layer 112. A portion of the high-k passivation layer 144 is conformally deposited on the sidewalls of the recess 508 as the high-k dielectric liner 148. In some implementations, the high-k dielectric liner 148 is also deposited on the bottom surface of the recess 508.

In some implementations, the high-k dielectric liner 148 is formed as a multiple-layer thin film. For example, a high-k dielectric liner 148a may be formed on the sidewalls of the recess 508, and a high-k dielectric liner 148b may be formed on the high-k dielectric liner 148a. As another example, a high-k dielectric liner 148a may be formed on the sidewalls of the recess 508, a high-k dielectric liner 148b may be formed on the high-k dielectric liner 148a, and a high-k dielectric liner 148c may be formed on the high-k dielectric liner 148c. In some implementations, the high-k dielectric liner 148 may include a greater quantity of layers.

A deposition tool may be used to deposit the high-k dielectric liner 148 (including the high-k dielectric liner 148a, the high-k dielectric liner 148b, and/or the high-k dielectric liner 148c) using an ALD technique, a CVD technique, and/or another suitable conformal deposition technique.

As shown in FIG. 5E, the low-k passivation layer 146 may be formed on the high-k passivation layer 144 over the back side of the semiconductor layer of the device layer 112. A portion of the low-k passivation layer 146 is conformally deposited on the sidewalls of the recess 508 over the high-k dielectric liner 148 as the low-k dielectric liner 150. In some implementations, the low-k dielectric liner 150 is also deposited on the bottom surface of the recess 508.

In some implementations, the low-k dielectric liner 150 is formed as a multiple-layer thin film. For example, a low-k passivation layer 146a may be formed on the back side of the device layer 112, resulting in formation of a low-k dielectric liner 150a on the sidewalls of the recess 508, and a low-k passivation layer 146b may be formed on the back side of the device layer 112, resulting in formation of a low-k dielectric liner 150b on the sidewalls of the recess 508 low-k dielectric liner 150a. In some implementations, the low-k dielectric liner 150 may include a greater quantity of layers.

A deposition tool may be used to deposit the low-k dielectric liner 150a using an ALD technique, a CVD technique, and/or another suitable conformal deposition technique. A deposition tool may be used to deposit the low-k dielectric liner 150b using an ALD technique (e.g., PEALD), a CVD technique, and/or another suitable conformal deposition technique.

As shown in FIG. 5F, the nitride-containing dielectric liner 152 may be conformally deposited on the sidewalls of the recess 508 over the low-k dielectric liner 150. In some implementations, the nitride-containing dielectric liner 152 is also deposited on the bottom surface of the recess 508. In some implementations, the nitride-containing dielectric liner 152 is also deposited on the back side of the semiconductor layer of the device layer 112 to protect the semiconductor layer from being damaged in a subsequent etch operation. A deposition tool may be used to deposit the nitride-containing dielectric liner 152 using an ALD technique (e.g., PEALD), a CVD technique (e.g., PECVD), and/or another suitable conformal deposition technique. The deposition process (e.g., PECVD) that is used to deposit the nitride-containing dielectric layer 152 result in the nitride-containing dielectric layer 152 being thicker at the top of the recess than at the bottom of the recess. This may result in an overhang of the material of the nitride-containing dielectric layer 152.

As shown in FIG. 5G, another etch operation may be performed to etch through the STI region 142 between the recess 508 and the underlying conductive structure 128 in the interconnect structure 114 to expose the conductive structure 128 through the recess 508. Thus, the depth of the recess 508 is increased from the first depth to a second depth during the etch operation.

In some implementations, the etch operation includes a dry etch operation (e.g., a plasma-based etch operation, a gas-based etch operation), a wet chemical etch operation, and/or another type of etch operation. In some implementations, the etch operation is performed as a self-aligned etch operation in that the recess 508 is etched without an additional patterned masking layer. The nitride-containing dielectric liner 152 may be included as an etch stop layer on the surface of the semiconductor layer of the device layer 112. Thus, the portion of the nitride-containing dielectric liner 152 formed on the back side of the semiconductor layer of the device layer 112 may protect the back side of the semiconductor layer from being etched during the etch operation. The portion of the nitride-containing dielectric liner 152 on the sidewalls of the recess 508 protects the sidewalls of the recess 508 from being etched. The overhang of the material of the nitride-containing dielectric layer 152 may result in the nitride-containing dielectric liner 152 on the bottom surface of the recess 508 being etched through, while some of the nitride-containing dielectric layer 152 of the recess 508 remains on the sidewalls of the recess 508 after the etch operation.

As shown in FIG. 5H, an elongated conductive structure 140 may be formed in the recess 508 such that the elongated conductive structure 140 lands on the underlying conductive structure 128. A deposition tool may be used to deposit the elongated conductive structure 140 using a CVD technique, a PVD technique, an ALD technique, an electroplating technique, and/or another suitable deposition technique. The elongated conductive structure 140 may be deposited in one or more deposition operations. In some implementations, a seed layer is first deposited, and the elongated conductive structure 140 is deposited on the seed layer. In some implementations, a planarization tool is used to perform a planarization operation (e.g., a CMP operation) to planarize the elongated conductive structure 140 after the elongated conductive structure 140 is deposited.

As indicated above, FIGS. 5A-5H are provided as an example. Other examples may differ from what is described with regard to FIGS. 5A-5H.

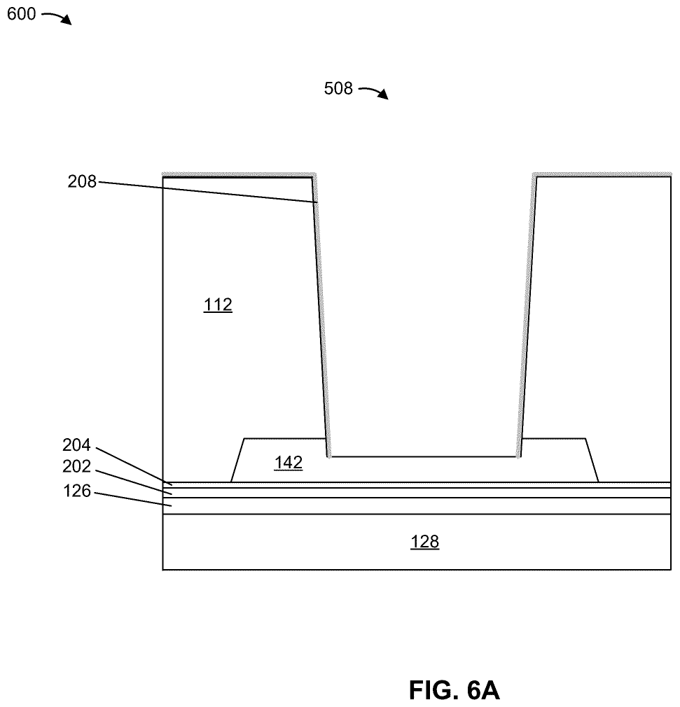

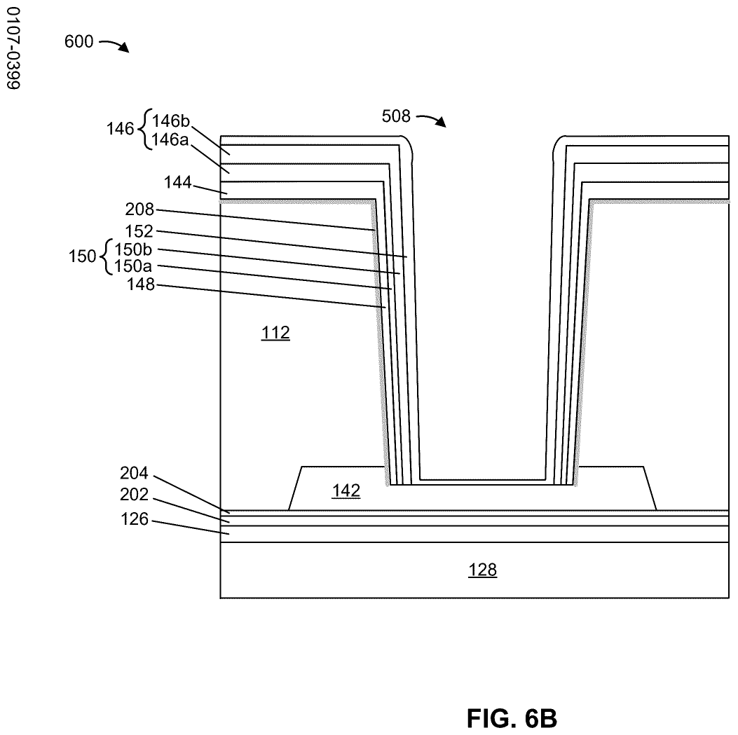

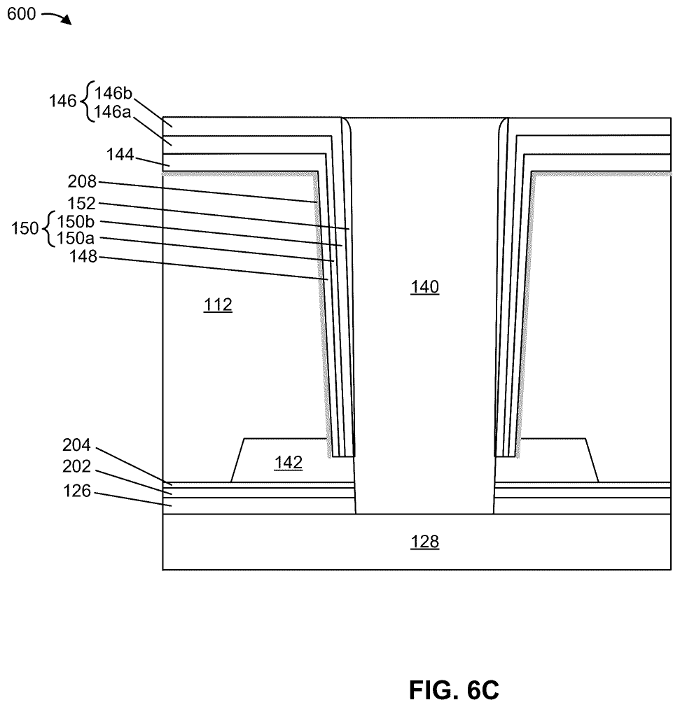

FIGS. 6A-6C are diagrams of an example implementation 500 of forming an elongated conductive structure 140 (e.g., a TSV) described herein. In some implementations, the example implementation 600 includes an example process for forming the elongated conductive structure 140 through the device layer 112 of the semiconductor die 104. In some implementations, one or more of the operations described in connection with the example implementation 600 may be performed to form an elongated conductive structure 140 through a device layer of another semiconductor die described herein, such as a device layer 108 of a semiconductor die 102, a device layer 804 of a semiconductor die 802 illustrated in FIGS. 8-10, and/or another semiconductor die described herein. In some implementations, one or more semiconductor processing tools may be used to perform one or more of the operations described in connection with the example implementation 600, such as a deposition tool, an exposure tool, a developer tool, an etch tool, a planarization tool, a plating tool, and/or another type of semiconductor processing tool.

As shown in FIG. 6A, similar semiconductor processing operations illustrated and described in connection with FIGS. 5A-5C may be performed to form the recess 508 in the back side of the semiconductor layer of the device layer 112.

As further shown in FIG. 6A, a low-k dielectric liner 208 may be formed on the sidewalls and bottom surface of the recess 508. In some implementations, the low-k dielectric liner 208 is also formed on the top surface of the back side of the semiconductor layer of the device layer 112. The low-k dielectric liner 208 may be formed on the sidewalls and bottom surface of the recess 508 to passivate surface damage (e.g., dangling bonds) that may have formed as a result of etching the semiconductor layer of the device layer 112 to form the recess 508. Additionally and/or alternatively, the low-k dielectric liner 208 may be formed as an adhesion layer for the high-k dielectric liner 148. A deposition tool may be used to deposit the low-k dielectric liner 208 using an ALD technique and/or another suitable conformal deposition technique.

As shown in FIGS. 6B and 6C, similar semiconductor processing operations as those described in connection with FIGS. 5D-5H may be performed to form the high-k dielectric liner 148 on the low-k dielectric liner 208, to form the low-k dielectric liner 150 on the high-k dielectric liner 148, to form the nitride-containing dielectric liner 152 on the low-k dielectric liner 150, and/or to form the elongated conductive structure 140 in the recess 508.

As indicated above, FIGS. 6A-6C are provided as an example. Other examples may differ from what is described with regard to FIGS. 6A-6C.

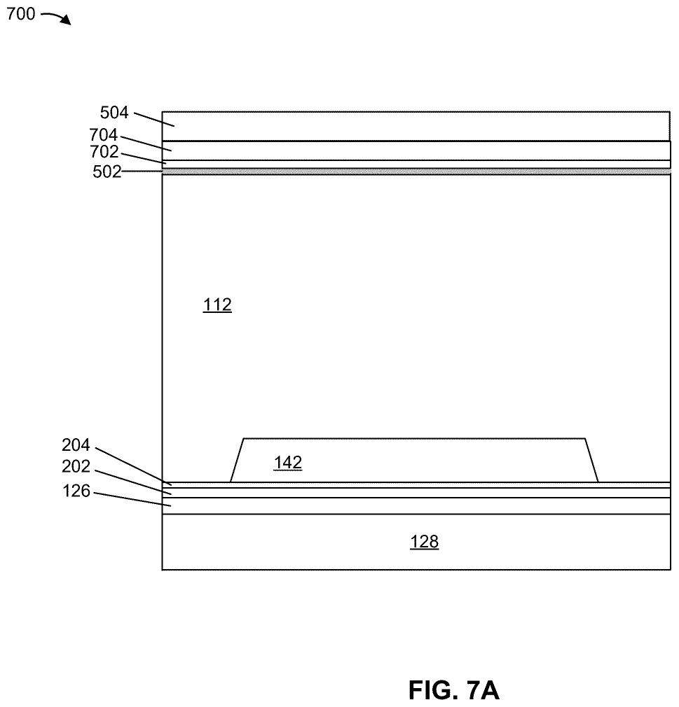

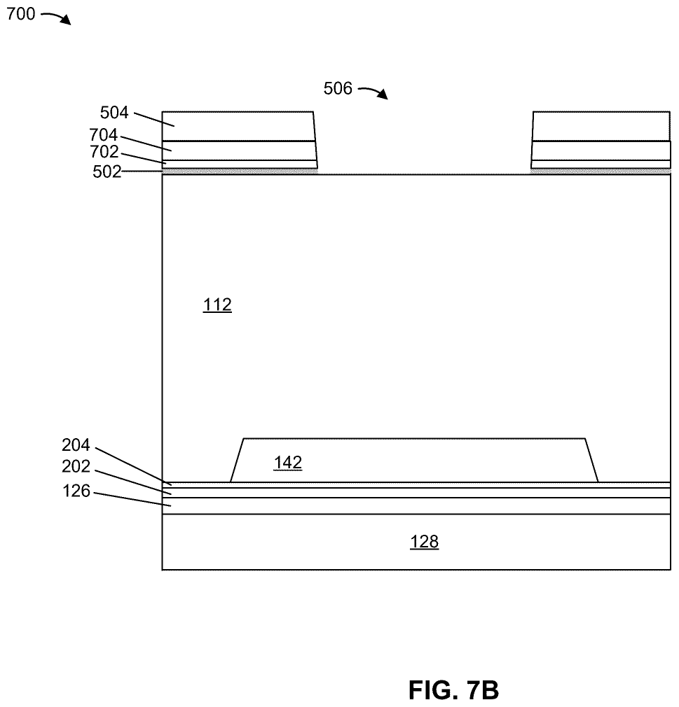

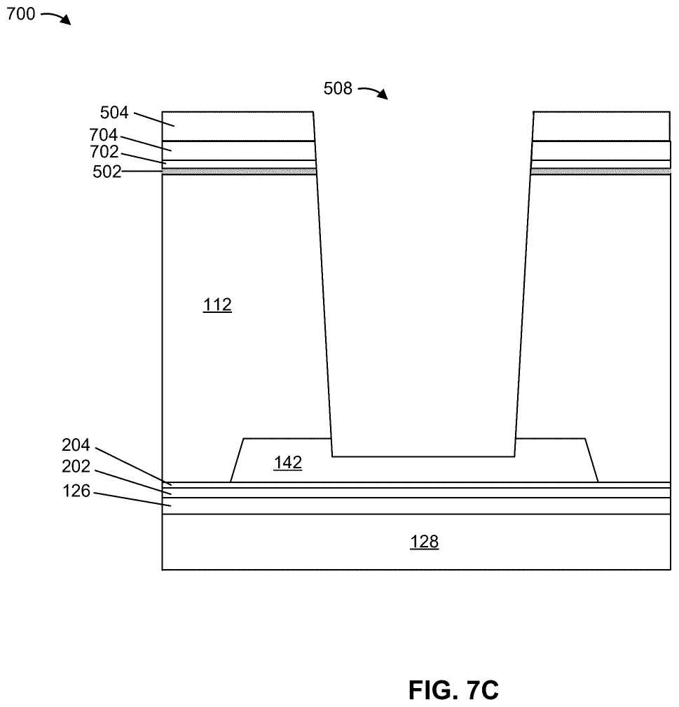

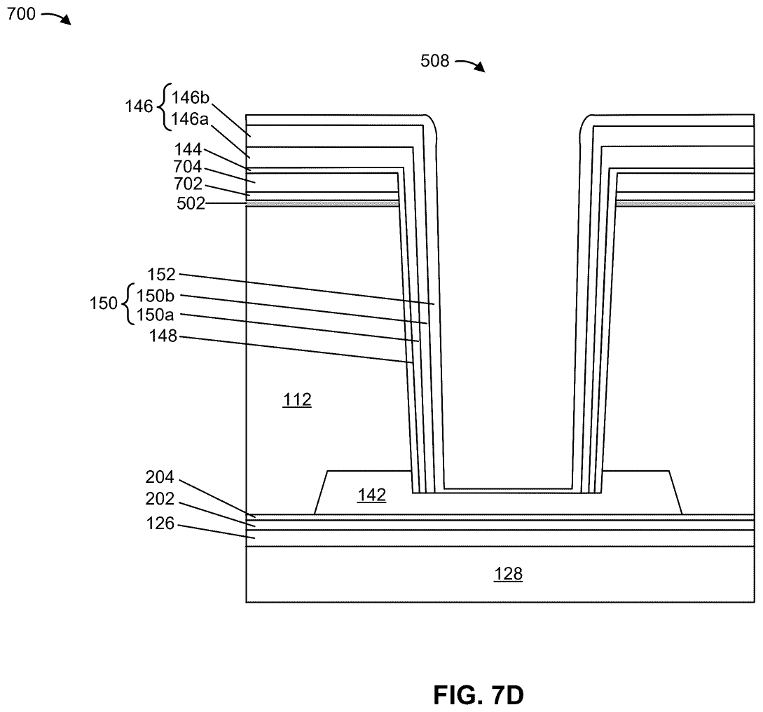

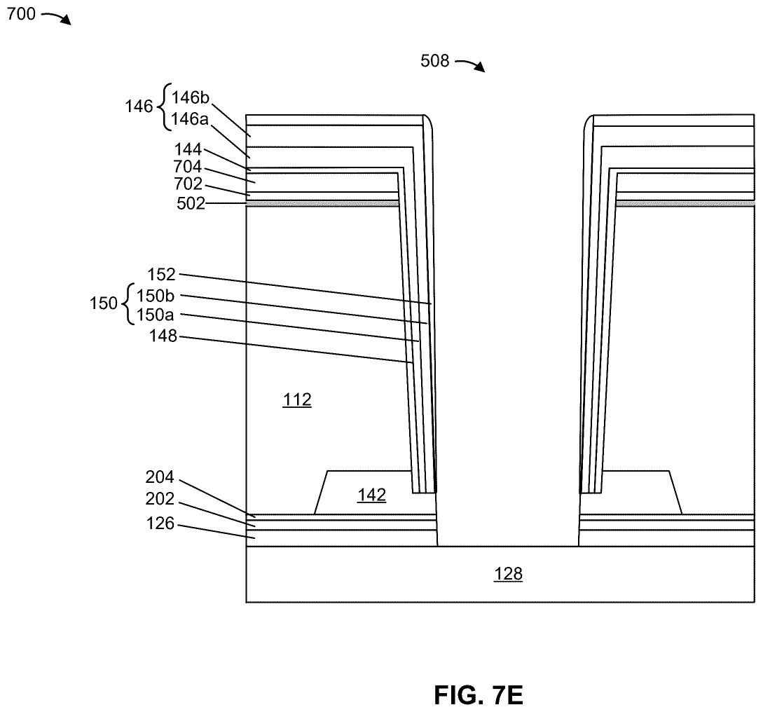

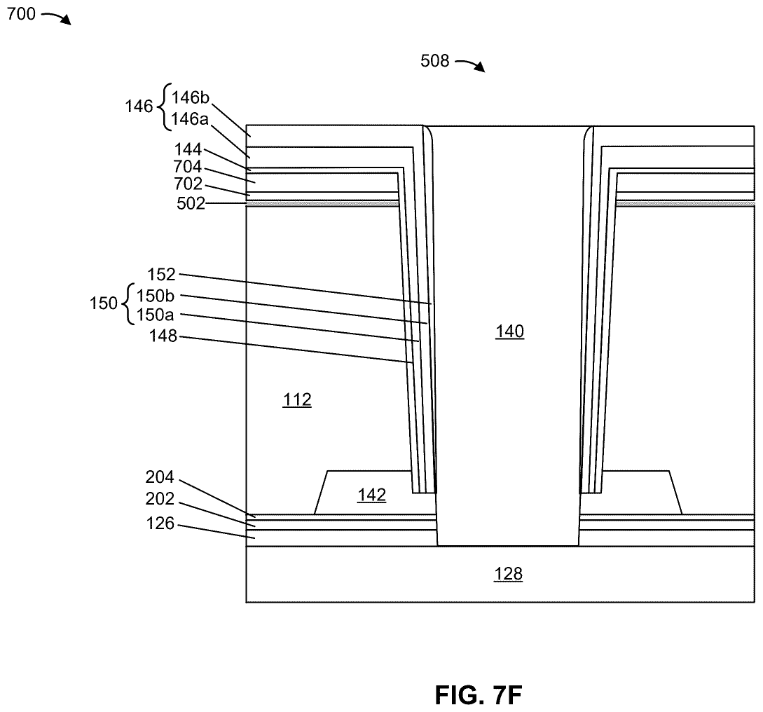

FIGS. 7A-7F are diagrams of an example implementation 700 of forming an elongated conductive structure 140 (e.g., a TSV) described herein. In some implementations, the example implementation 700 includes an example process for forming the elongated conductive structure 140 through the device layer 112 of the semiconductor die 104. In some implementations, one or more of the operations described in connection with the example implementation 700 may be performed to form an elongated conductive structure 140 through a device layer of another semiconductor die described herein, such as a device layer 108 of a semiconductor die 102, a device layer 804 of a semiconductor die 802 illustrated in FIGS. 8-10, and/or another semiconductor die described herein. In some implementations, one or more semiconductor processing tools may be used to perform one or more of the operations described in connection with the example implementation 700, such as a deposition tool, an exposure tool, a developer tool, an etch tool, a planarization tool, a plating tool, and/or another type of semiconductor processing tool.

As shown in FIG. 7A, the low-k buffer layer 502 and the masking layer 504 are formed over the back side of the semiconductor layer of the device layer 112, similar to as described in FIG. 5A. However, a high-k passivation layer 702 and a low-k passivation layer 704 are formed over the low-k buffer layer 502 prior to formation of the masking layer 504. The masking layer 504 is formed on the low-k passivation layer 704. A deposition tool may be used to deposit the high-k passivation layer 702 and the low-k passivation layer 704, each using a PVD technique, an ALD technique, a CVD technique, an oxidation technique, and/or another suitable deposition technique. In some implementations, a planarization tool may be used to perform a planarization operation (e.g., a CMP operation) to planarize the high-k passivation layer 702 and/or the low-k passivation layer 704.

As shown in FIG. 7B, the pattern 506 may be formed in the masking layer 504 in a similar manner as described in connection with FIG. 5B, except that the pattern 506 is transferred to the high-k passivation layer 702 and the low-k passivation layer 704.

As shown in FIG. 7C, an etch tool may be used to perform an etch operation to etch the semiconductor layer of the device layer 112 based on the pattern 506 in the masking layer 504, the high-k passivation layer 702, and the low-k passivation layer 704 to form the recess 508.

As shown in FIG. 7D, the high-k dielectric liner 148, the low-k dielectric liner 150, and the nitride-containing liner 152 are formed on the sidewalls of the recess 508 in a similar manner as described in connection with FIGS. 5D-5F.

As shown in FIG. 7E, another etch operation may be performed to etch through the STI region 142 between the recess 508 and the underlying conductive structure 128 in the interconnect structure 114 to expose the conductive structure 128 through the recess 508 in a similar manner as described in connection with FIG. 5G.

As shown in FIG. 7F, an elongated conductive structure 140 may be formed in the recess 508, in a similar manner as described in connection with FIG. 5H, such that the elongated conductive structure 140 lands on the underlying conductive structure 128.

As indicated above, FIGS. 7A-7F are provided as an example. Other examples may differ from what is described with regard to FIGS. 7A-7F.

FIG. 8 is a diagram of an example semiconductor die package 800 described herein. As shown in FIG. 8, the semiconductor die package 800 includes a similar combination and arrangement of structures and layers as the semiconductor die package 100. For example, the semiconductor die package 800 includes the semiconductor die 102 and the semiconductor die 104 bonded at a bonding interface. The semiconductor die package 800 similarly includes an elongated conductive structure 140 through the device layer 112 of the semiconductor die 104 that is formed using techniques described herein, such as in connection with FIGS. 5A-5H, 6A-6C, and/or 7A-7F, among other examples.

However, as shown in FIG. 8, the semiconductor die package 800 may include an additional semiconductor die 802 that is bonded with the semiconductor die 104 at another bonding interface 106b. Thus, the semiconductor die 104 is bonded with the semiconductor die 102 at the bonding interface 106a located on a front side of the device layer 112, and bonded with the semiconductor die 802 at the bonding interface 106b located on a back side of the device layer 112, in a three-die stacking arrangement. The semiconductor die 102 and the semiconductor die 104 may be bonded at the bonding interface 106a, and the semiconductor die 104 and the semiconductor die 802 may be bonded at the bonding interface 106b, using similar bonding techniques as described in connection with FIGS. 4A and 4B.

The semiconductor die 802 may include a device layer 804, an interconnect structure 806, one or more integrated circuit devices 808 in the device layer 804, one or more dielectric layers 810 and a plurality of conductive structures 812 in the interconnect structure 806, and bonding pads 814 that are bonded with the connection structures 138 (which may also be implemented as bonding pads in the semiconductor die package 800) at the bonding interface 106b.

Each of the semiconductor dies 102, 104, and 802 may include a different functionality. For example, the semiconductor die 102 may include a capacitor die (e.g., a deep trench capacitor (DTC) die), the semiconductor die 104 may include a logic die, and the semiconductor die 802 may include a memory die (e.g., a dynamic random access memory (DRAM) die). Alternatively, two or more of the semiconductor dies 102, 104, and/or 802 may include similar functionality.

The elongated conductive structure 140 may enable signals and/or power to be provided between the interconnect structure 114 of the semiconductor die 104 and the interconnect structure 806 of the semiconductor die 802. In some implementations, the elongated conductive structure 140 may enable signals and/or power to be provided between the interconnect structure 110 of the semiconductor die 102 and the interconnect structure 806 of the semiconductor die 802 through the interconnect structure 114 of the semiconductor die 104. One or more combinations and/or arrangements of liners illustrated in FIGS. 2A-2F may be provided between the elongated conductive structure 140 and the device layer 112.

As indicated above, FIG. 8 is provided as an example. Other examples may differ from what is described with regard to FIG. 8.

FIG. 9 is a diagram of an example semiconductor die package 900 described herein. As shown in FIG. 9, the semiconductor die package 900 includes a similar combination and arrangement of structures and layers as the semiconductor die package 800. For example, the semiconductor die package 900 includes the semiconductor die 102 and the semiconductor die 104 bonded at the bonding interface 106a, and the semiconductor die 802 bonded with the semiconductor die 104 at the bonding interface 106b. The semiconductor die package 900 similarly includes an elongated conductive structure 140, through the device layer 112 of the semiconductor die 104, that electrically couples the interconnect structure 114 of the semiconductor die 104 and the interconnect structure 806 of the semiconductor die 802. The elongated conductive structure 140 is formed using techniques described herein, such as in connection with FIGS. 5A-5H, 6A-6C, and/or 7A-7F, among other examples.

However, as shown in FIG. 9, the semiconductor die 102 in the semiconductor die package 900 may include an additional interconnect structure 902 on the back side of the device layer 108. The interconnect structure 902 includes one or more dielectric layers 904 and one or more conductive structures 906 in the one or more dielectric layers 904.

Moreover, the semiconductor die package 900 may include another elongated conductive structure 140 through the device layer 108 of the semiconductor die 102. The elongated conductive structure 140 through the device layer 108 of the semiconductor die 102 electrically couples the interconnect structure 110 on the front side of the device layer 108 of the semiconductor die 102 and the interconnect structure 902 on the back side of the device layer 108 of the semiconductor die 102. The elongated conductive structure 140 through the device layer 108 may be electrically coupled and/or physically coupled with a conductive structure 122 in the interconnect structure 110 and a conductive structure 906 in the interconnect structure 902. One or more combinations and/or arrangements of liners illustrated in FIGS. 2A-2F may be provided between the elongated conductive structure 140 and the device layer 108. The elongated conductive structure 140 is formed using techniques described herein, such as in connection with FIGS. 5A-5H, 6A-6C, and/or 7A-7F, among other examples.

The elongated conductive structure 140 through the device layer 108 may enable signals and/or power to be provided between the interconnect structure 110 of the semiconductor die 102 and the interconnect structure 902 of the semiconductor die 102. In some implementations, the elongated conductive structure 140 through the device layer 108 enables backside power delivery to be provided to the semiconductor die package 900 through the device layer 108.

As indicated above, FIG. 9 is provided as an example. Other examples may differ from what is described with regard to FIG. 9.

FIG. 10 is a diagram of an example semiconductor die package 1000 described herein. As shown in FIG. 10, the semiconductor die package 1000 includes a similar combination and arrangement of structures and layers as the semiconductor die package 800. For example, the semiconductor die package 1000 includes the semiconductor die 102 and the semiconductor die 104 bonded at the bonding interface 106a, and the semiconductor die 802 bonded with the semiconductor die 104 at the bonding interface 106b. The semiconductor die package 1000 similarly includes an elongated conductive structure 140, through the device layer 112 of the semiconductor die 104, that electrically couples the interconnect structure 114 of the semiconductor die 104 and the interconnect structure 806 of the semiconductor die 802. The elongated conductive structure 140 is formed using techniques described herein, such as in connection with FIGS. 5A-5H, 6A-6C, and/or 7A-7F, among other examples.

However, as shown in FIG. 10, the semiconductor die 102 may include an image sensor die such as a complementary metal-oxide-semiconductor (CMOS) image sensor die. Accordingly, the semiconductor die 102 may include a pixel sensor array 1002 that includes a plurality of pixel sensors, a black level correction (BLC) region 1004, and a bonding pad region 1006 on the back side of the device layer 108. A seal ring region 1008 may be included around the pixel sensor array 1002, the BLC region 1004, and/or the bonding pad region 1006.

The pixel sensors in the pixel sensor array 1002 are configured to sense and/or accumulate incident light and to generate a photocurrent based on the accumulation of incident light. The BLC region 1004 includes a region of the device layer 108 (e.g., a sensing region) that is shielded by a metal layer so that dark current measurements may be performed in the BLC region 1004. A dark current measurement may be performed to measure the amount of charge (dark current) in the device layer 108 that is generated from sources other than incident light (e.g., from thermal energy in the device layer 108) so that the dark current measurement may be used for black level correction (or black level calibration) for the pixel sensors of the pixel sensor array 1002. The bonding pad region 1006 may include a bonding pad structure that may be connected to an external electrical connection. The seal ring region 1008 includes a plurality of stacked conductive structures 122 in the interconnect structure 110 to seal the structures and layers of the pixel sensor array 1002 to prevent ingress of humidity and other contaminants, as well as to provide structural rigidity to the semiconductor die 102.

The integrated circuit devices 118 of the semiconductor die 104 may include one or more application-specific integrated circuit (ASIC) devices, one or more system-on-chip (SOC) devices, one or more transistors, and/or one or more other components configured to measure the magnitude of a photocurrent generated by the pixel sensors of the pixel sensor array 1002 to determine light intensity of incident light and/or to generate images and/or video (e.g., digital images, digital video). The integrated circuit devices 808 of the semiconductor die 802 may include memory devices (e.g., DRAM cells) for storing data associated with images and/or video generated by the pixel sensors of the pixel sensor array 1002.

The elongated conductive structure 140 may enable the data associated with the images and/or video to be provided from the semiconductor die 104 to the semiconductor die 802 (or vice-versa) through the device layer 112. One or more combinations and/or arrangements of liners illustrated in FIGS. 2A-2F may be provided between the elongated conductive structure 140 and the device layer 112. Moreover, the elongated conductive structure 140 is formed using techniques described herein, such as in connection with FIGS. 5A-5H, 6A-6C, and/or 7A-7F, among other examples.

As indicated above, FIG. 10 is provided as an example. Other examples may differ from what is described with regard to FIG. 10.

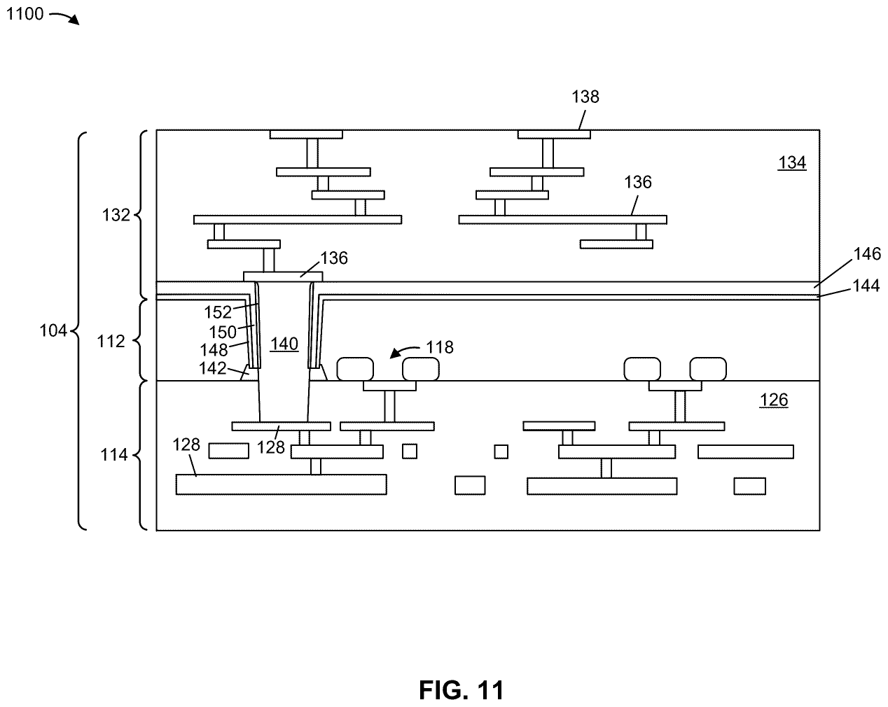

FIG. 11 is a diagram of an example semiconductor die package 1100 described herein. As shown in FIG. 11, the semiconductor die package 1100 includes a single-die semiconductor die package in which only the semiconductor die 104 is included. The semiconductor die package 1100 includes an elongated conductive structure 140 through the device layer 112 of the semiconductor die 104. The elongated conductive structure 140 may enable the data associated with the images and/or video to be provided between the interconnect structure 114 and the interconnect structure 132 of the semiconductor die 104, and may enable backside power delivery to be provided to the interconnect structure 114 on the front side of the device layer 112 through the device layer 112. One or more combinations and/or arrangements of liners illustrated in FIGS. 2A-2F may be provided between the elongated conductive structure 140 and the device layer 112. Moreover, the elongated conductive structure 140 is formed using techniques described herein, such as in connection with FIGS. 5A-5H, 6A-6C, and/or 7A-7F, among other examples.

As indicated above, FIG. 11 is provided as an example. Other examples may differ from what is described with regard to FIG. 11.

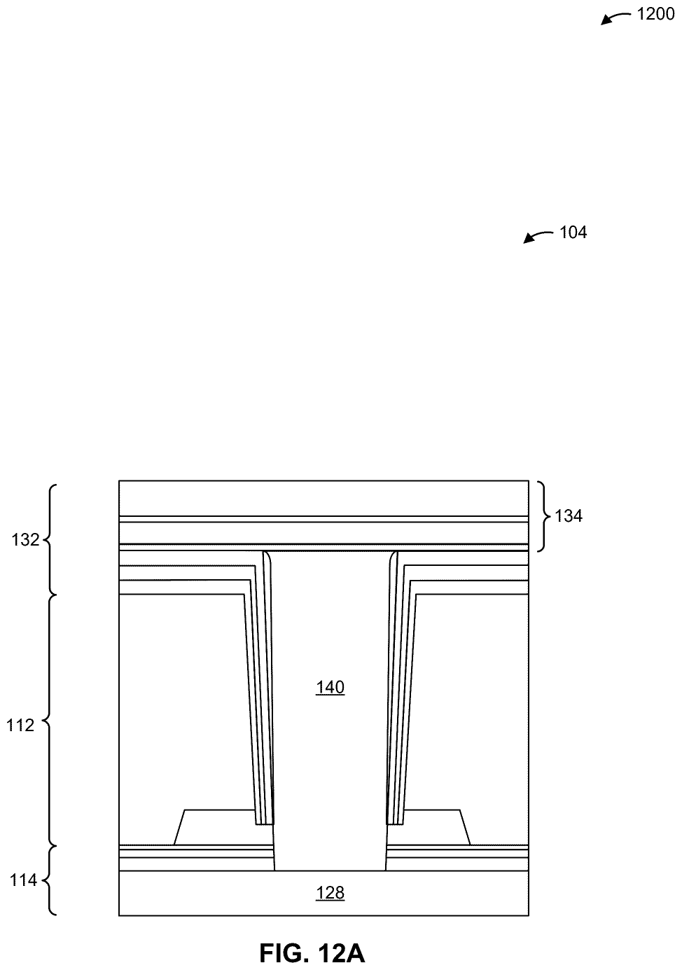

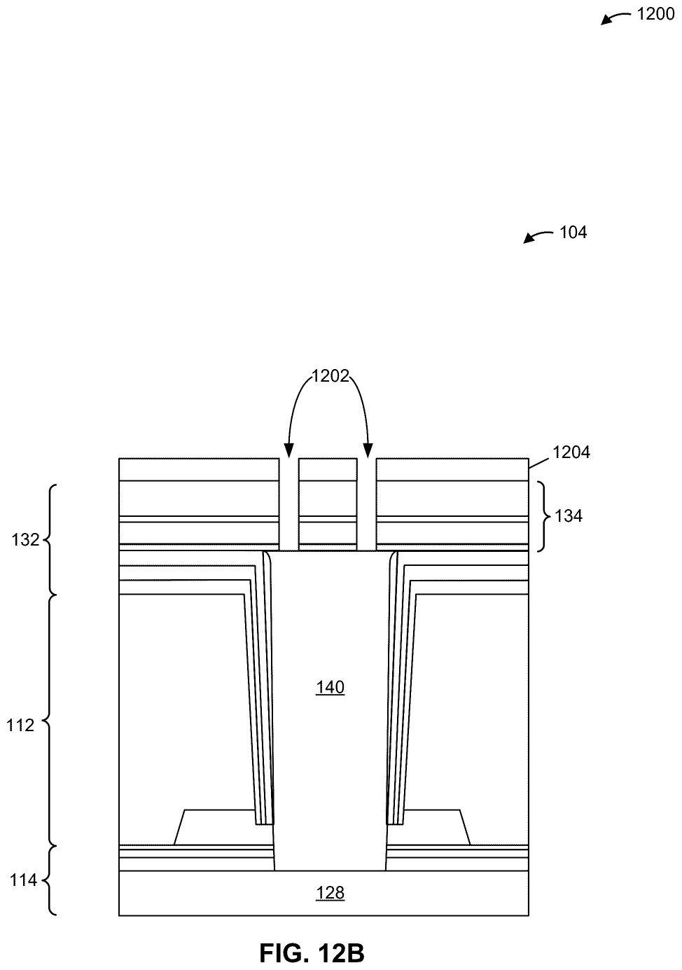

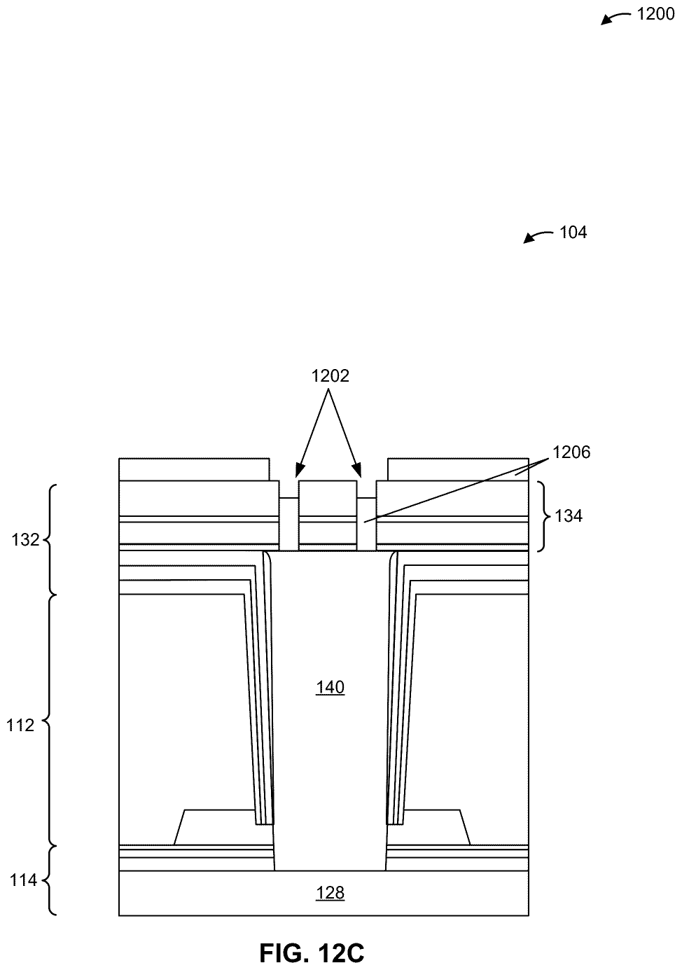

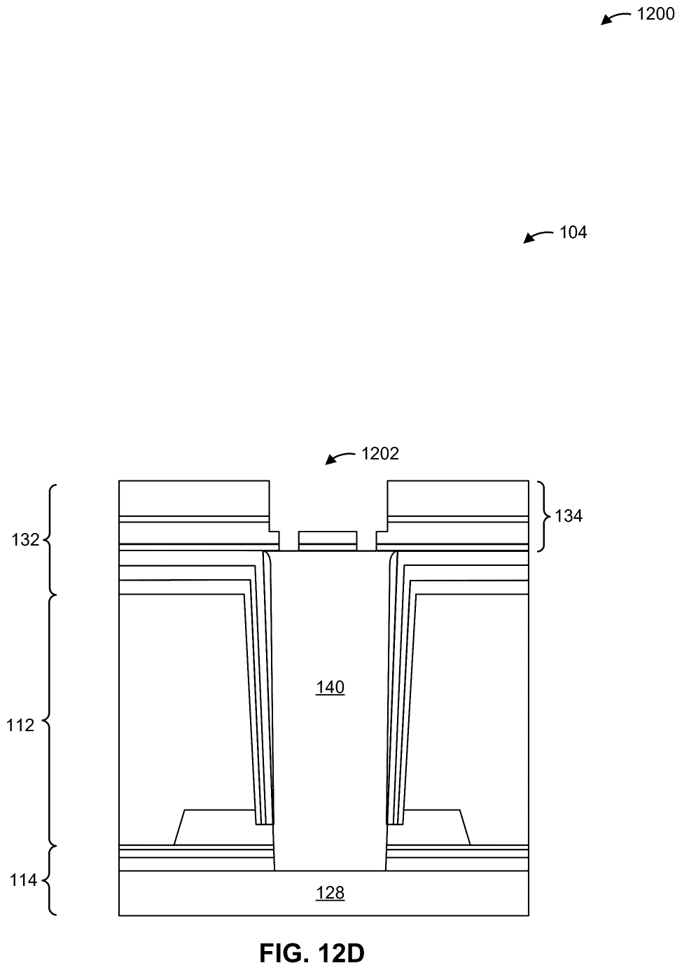

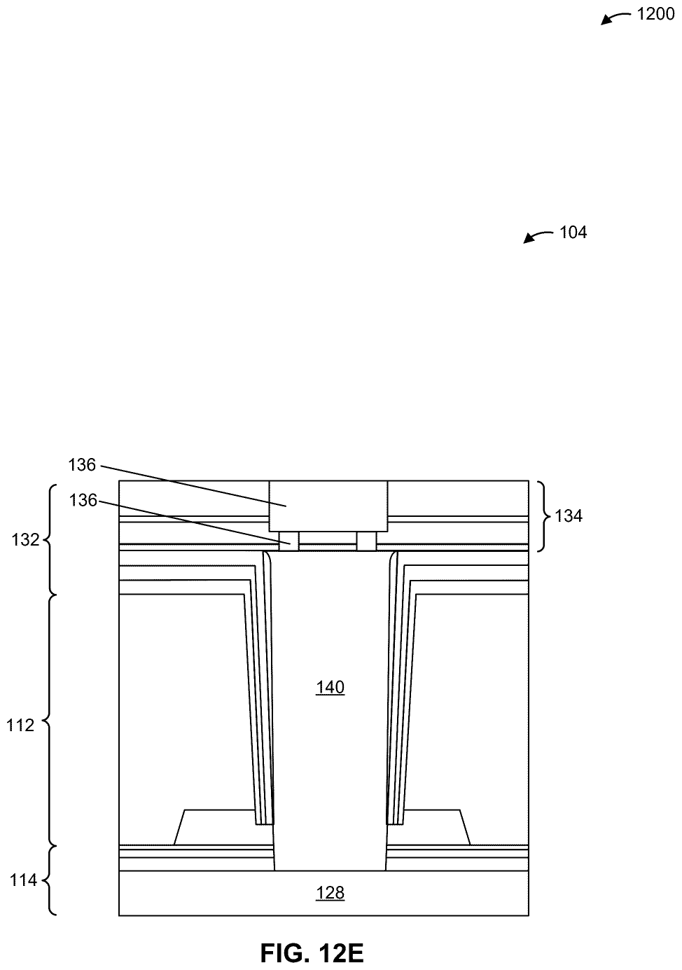

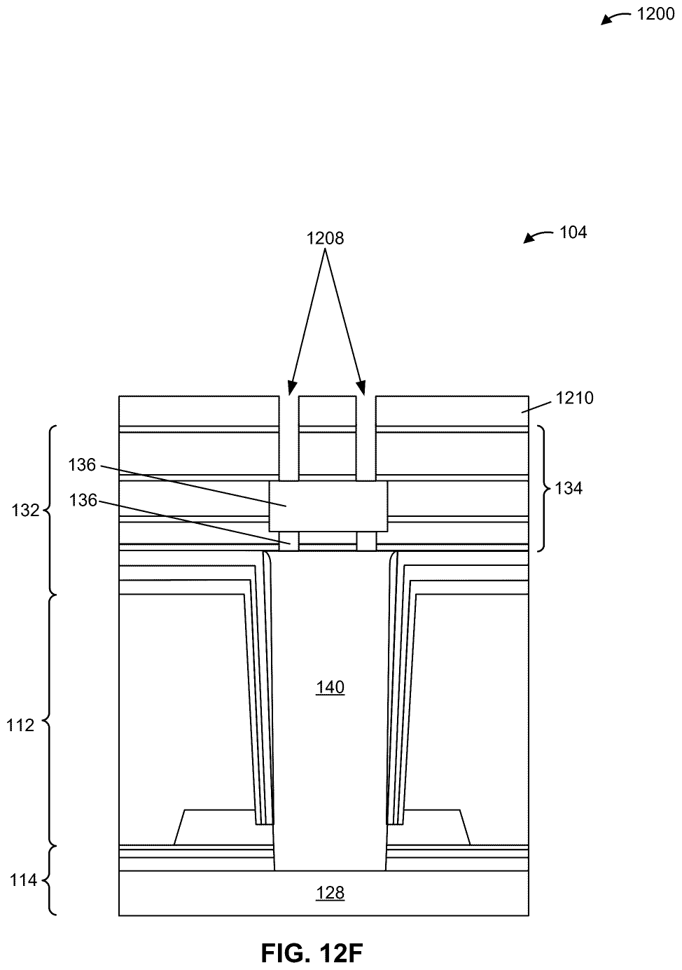

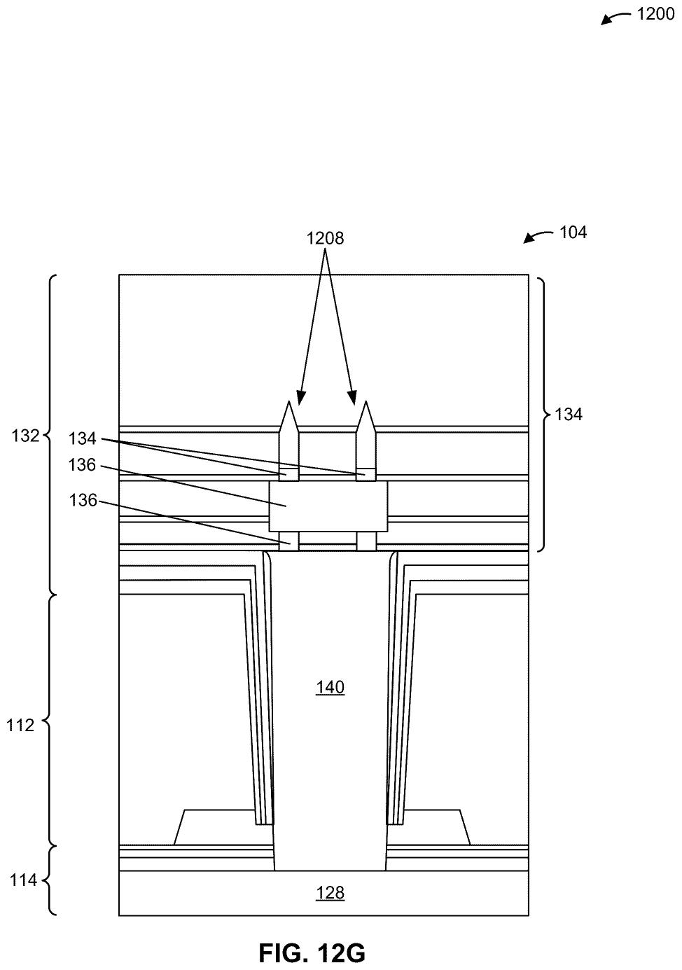

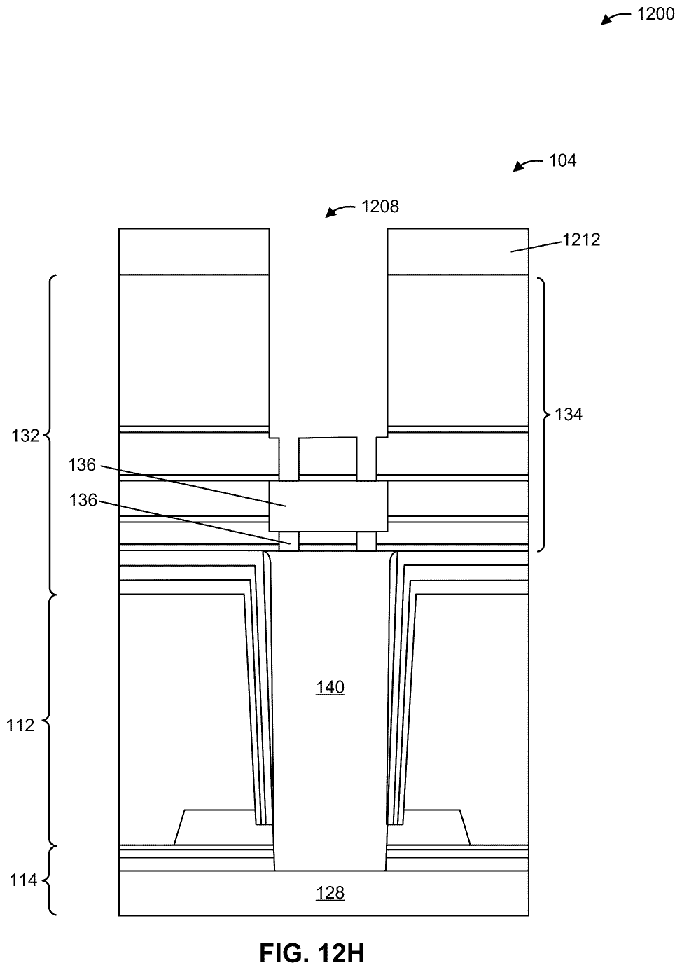

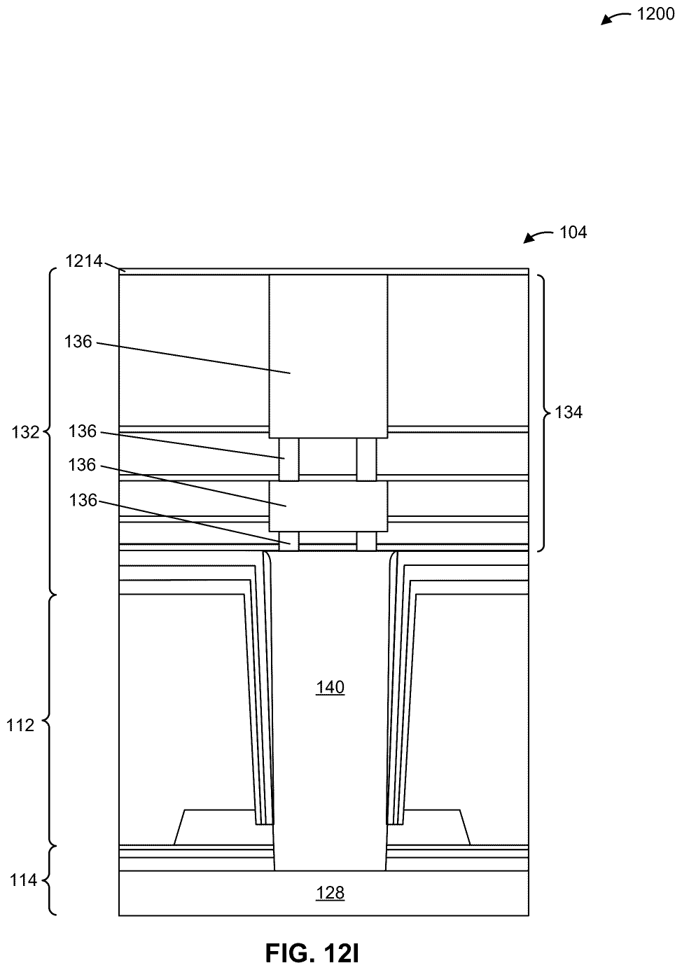

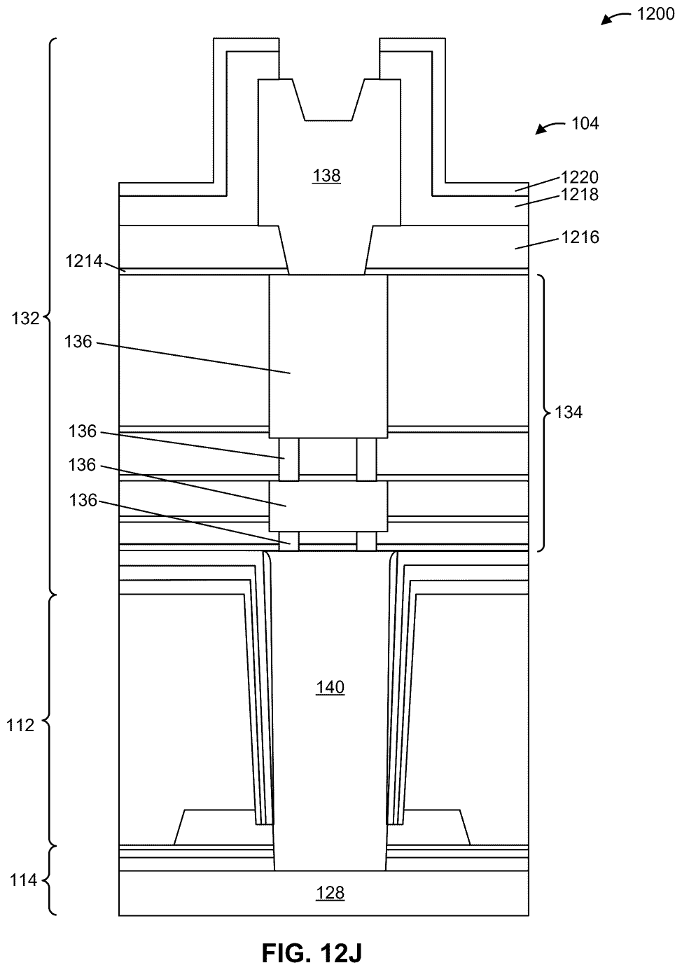

FIGS. 12A-12J are diagrams of an example implementation 1200 of forming an interconnect structure 132 of a semiconductor die 104 described herein. In some implementations, one or more semiconductor processing tools may be used to perform one or more of the operations described in connection with the example implementation 1200, such as a deposition tool, an exposure tool, a developer tool, an etch tool, a planarization tool, a plating tool, and/or another type of semiconductor processing tool.

As shown in FIG. 12A, one or more of the dielectric layers 134 of the interconnect structure 132 may be formed over the back side of the semiconductor layer of the device layer 112.

A deposition tool may be used to deposit the dielectric layer(s) 134 using a PVD technique, an ALD technique, a CVD technique, an oxidation technique, and/or another suitable deposition technique. The dielectric layer(s) 134 may be deposited in one or more deposition operations. In some implementations, a planarization tool may be used to perform a planarization operation (e.g., a CMP operation) to planarize the dielectric layer(s) 134 after the dielectric layer(s) 134 are deposited.

As shown in FIG. 12B, first portions of a recess 1202 are formed through the dielectric layer(s) 134 to the elongated conductive structure 140. The first portions of the recess 1202 may be referred to as via portions of the recess 1202. In some implementations, a pattern in a photoresist layer 1204 is used to etch the dielectric layer(s) 134 to form the pattern. In these implementations, a deposition tool may be used to form the photoresist layer 1204 on the dielectric layer(s) 134 using a spin-coating technique. An exposure tool may be used to expose the photoresist layer 1204 to a radiation source to pattern the photoresist layer 1204. A developer tool may be used to develop and remove portions of the photoresist layer 1204 to expose the pattern. An etch tool may be used to etch the dielectric layer(s) 134 based on the pattern to form the first portions of the recess 1202. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 1204 (e.g., using a chemical stripper, plasma ashing, and/or another technique). In some implementations, a hard mask layer is used as an alternative technique for etching the dielectric layer(s) 134 based on a pattern.

As shown in FIG. 12C, another photoresist layer 1206 may be formed on the dielectric layer(s) 134 and in the first portions of the recess 1202. A deposition tool may be used to form the photoresist layer 1206 on the dielectric layer(s) 134 and in the first portions of the recess 1202 using a spin-coating technique.

As shown in FIG. 12D, an etch tool may be used to etch the dielectric layer(s) 134 based on the photoresist layer 1206 to form a second portion of the recess 1202. The second portion of the recess 1202 corresponds to a trench portion of the recess 1202. Accordingly, the recess 1202 may include a dual damascene recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 1206 (e.g., using a chemical stripper, plasma ashing, and/or another technique).

As shown in FIG. 12E, one or more conductive structures 136 of the interconnect structure 132 may be formed in the recess 1202. For example, one or more vias may be formed in the via portions of the recess 1202. As another example, a metallization layer may be formed in the trench portion of the recess 1202. A deposition tool may be used to deposit the conductive structure(s) 136 using a CVD technique, a PVD technique, an ALD technique, an electroplating technique, and/or another suitable deposition technique. The conductive structure(s) 136 may be deposited in one or more deposition operations. In some implementations, a seed layer is first deposited, and the conductive structure(s) 136 are deposited on the seed layer. In some implementations, a planarization tool is used to perform a planarization operation (e.g., a CMP operation) to planarize the conductive structure(s) 136 after the conductive structure(s) 136 are deposited.

As shown in FIG. 12F, one or more additional dielectric layers 134 of the interconnect structure 132 may be formed over the back side of the semiconductor layer of the device layer 112. A deposition tool may be used to deposit the dielectric layer(s) 134 using a PVD technique, an ALD technique, a CVD technique, an oxidation technique, and/or another suitable deposition technique. The dielectric layer(s) 134 may be deposited in one or more deposition operations. In some implementations, a planarization tool may be used to perform a planarization operation (e.g., a CMP operation) to planarize the dielectric layer(s) 134 after the dielectric layer(s) 134 are deposited.

As further shown in FIG. 12F, first portions of a recess 1208 are formed through the dielectric layer(s) 134 to the underlying conductive structure 136. The first portions of the recess 1208 may be referred to as via portions of the recess 1208. In some implementations, a pattern in a photoresist layer 1210 is used to etch the dielectric layer(s) 134 to form the pattern. In these implementations, a deposition tool may be used to form the photoresist layer 1210 on the dielectric layer(s) 134 using a spin-coating technique. An exposure tool may be used to expose the photoresist layer 1210 to a radiation source to pattern the photoresist layer 1210. A developer tool may be used to develop and remove portions of the photoresist layer 1210 to expose the pattern. An etch tool may be used to etch the dielectric layer(s) 134 based on the pattern to form the first portions of the recess 1208. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 1210 (e.g., using a chemical stripper, plasma ashing, and/or another technique). In some implementations, a hard mask layer is used as an alternative technique for etching the dielectric layer(s) 134 based on a pattern.

As shown in FIG. 12G, one or more additional dielectric layers 134 of the interconnect structure 132 may be formed over the back side of the semiconductor layer of the device layer 112. A deposition tool may be used to deposit the dielectric layer(s) 134 using a PVD technique, an ALD technique, a CVD technique, an oxidation technique, and/or another suitable deposition technique. The dielectric layer(s) 134 may be deposited in one or more deposition operations. In some implementations, a planarization tool may be used to perform a planarization operation (e.g., a CMP operation) to planarize the dielectric layer(s) 134 after the dielectric layer(s) 134 are deposited. The dielectric layer(s) 134 may seal the first portions of the recess 1208. In some implementations, some amount of material of the dielectric layer(s) 134 is deposited in the first portions of the recess 1208 as the material of the dielectric layer(s) 134 seals the first portions of the recess 1208.

As shown in FIG. 12H, an etch tool may be used to etch the dielectric layer(s) 134 based on a pattern in another photoresist layer 1212 to form a second portion of the recess 1208. The second portion of the recess 1208 corresponds to a trench portion of the recess 1208. Accordingly, the recess 1208 may include a dual damascene recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 1212 (e.g., using a chemical stripper, plasma ashing, and/or another technique).

The dielectric layer(s) 134 may be etched such that the trench portion is formed down to the via portions of the recess 1208. As the etching proceeds through the dielectric layer(s) 134 to the via portions of the recess 1208, the via portions of the recess 1208 are opened up, and the material of the dielectric layer(s) 134 that was deposited in the via portions of the recess 1208 as described in connection with FIG. 12G is etched and removed.

As shown in FIG. 12I, one or more conductive structures 136 of the interconnect structure 132 may be formed in the recess 1208. For example, one or more vias may be formed in the via portions of the recess 1208. As another example, a metallization layer may be formed in the trench portion of the recess 1208. A deposition tool may be used to deposit the conductive structure(s) 136 using a CVD technique, a PVD technique, an ALD technique, an electroplating technique, and/or another suitable deposition technique. The conductive structure(s) 136 may be deposited in one or more deposition operations. In some implementations, a seed layer is first deposited, and the conductive structure(s) 136 are deposited on the seed layer. In some implementations, a planarization tool is used to perform a planarization operation (e.g., a CMP operation) to planarize the conductive structure(s) 136 after the conductive structure(s) 136 are deposited.

As further shown in FIG. 12I, a barrier layer 1214 is formed on the conductive structure(s) 136 to prevent, minimize, and/or otherwise reduce the likelihood of upward material migration from the conductive structure(s) 136 to structures that are subsequently formed above the conductive structure(s) 136. The barrier layer 1214 may also function as an etch stop layer for etching layers that are subsequently formed above the conductive structure(s) 136. The barrier layer 1214 may include silicon nitride (SiₓN_{y}), tantalum nitride (TaN), and/or another suitable barrier material. A deposition tool may be used to deposit the barrier layer 1214 using a CVD technique, an ALD technique (e.g., a PECVD technique, a PEALD technique), and/or another suitable deposition technique.

As shown in FIG. 12J, one or more backside passivation layers 1216 are formed over the back side of the device layer 112. Connection structures 138 may be formed through the backside passivation layer(s) 1216 and barrier layer 1214 such that the connection structures 138 are coupled to one or more conductive structures 136 in the interconnect structure 132. Additional backside passivation layers 1218 and/or 1220 may be formed over the connection structures 138.

As indicated above, FIGS. 12A-12J are provided as an example. Other examples may differ from what is described with regard to FIGS. 12A-12J.

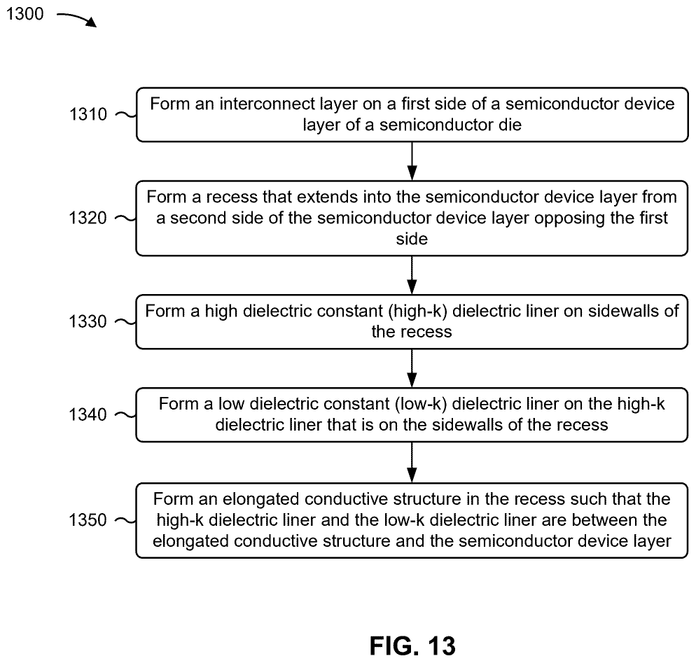

FIG. 13 is a flowchart of an example process 1300 associated with forming a semiconductor die package described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming an interconnect structure on a first side of a semiconductor device layer of a semiconductor die (block 1310). For example, one or more semiconductor processing tools may be used to form an interconnect structure (e.g., an interconnect structure 110, an interconnect structure 114) on a first side of a semiconductor device layer (e.g., a semiconductor layer of a device layer 108, a semiconductor layer of a device layer 112) of a semiconductor die (e.g., a semiconductor die 102, a semiconductor die 104), as described herein.

As further shown in FIG. 13, process 1300 may include forming a recess that extends into the semiconductor device layer from a second side of the semiconductor device layer opposing the first side (block 1320). For example, one or more semiconductor processing tools may be used to form a recess (e.g., a recess 508) that extends into the semiconductor device layer from a second side (e.g., a back side) of the semiconductor device layer opposing the first side, as described herein.

As further shown in FIG. 13, process 1300 may include forming a high-k dielectric liner on sidewalls of the recess (block 1330). For example, one or more semiconductor processing tools may be used to form a high-k dielectric liner (e.g., a high-k dielectric liner 148, a high-k dielectric liner 148a, a high-k dielectric liner 148b, a high-k dielectric liner 148c) on sidewalls of the recess, as described herein.

As further shown in FIG. 13, process 1300 may include forming a low-k dielectric liner on the high-k dielectric liner that is on the sidewalls of the recess (block 1340). For example, one or more semiconductor processing tools may be used to form a low-k dielectric liner (e.g., a low-k dielectric liner 150, a low-k dielectric liner 150a, a low-k dielectric liner 150b) on the high-k dielectric liner that is on the sidewalls of the recess, as described herein.

As further shown in FIG. 13, process 1300 may include forming an elongated conductive structure in the recess such that the high-k dielectric liner and the low-k dielectric liner are between the elongated conductive structure and the semiconductor device layer (block 1350). For example, one or more semiconductor processing tools may be used to form an elongated conductive structure (e.g., an elongated conductive structure 140) in the recess such that the high-k dielectric liner and the low-k dielectric liner are between the elongated conductive structure and the semiconductor device layer, as described herein.

Process 1300 may include additional implementations, such as any single implementation or any combination of implementations described below and/or in connection with one or more other processes described elsewhere herein.

In a first implementation, forming the recess includes forming the recess such that a bottom surface of the recess extends into a STI region (e.g., a STI region 142) in the semiconductor device layer, and forming the high-k dielectric liner comprises forming the high-k dielectric liner on a portion of the sidewalls of the recess in the STI region.

In a second implementation, alone or in combination with the first implementation, the high-k dielectric liner includes an oxide-containing high-k dielectric material.

In a third implementation, alone or in combination with one or more of the first and second implementations, process 1300 includes forming another high-k dielectric liner (e.g., another high-k dielectric liner 148, another high-k dielectric liner 148a, another high-k dielectric liner 148b, another high-k dielectric liner 148c) on the low-k dielectric liner prior to forming the elongated conductive structure.

In a fourth implementation, alone or in combination with one or more of the first through third implementations, the high-k dielectric liner includes a high-k dielectric material having a dielectric constant that is greater than a dielectric constant of silicon nitride (SiₓN_{y}).

In a fifth implementation, alone or in combination with one or more of the first through fourth implementations, process 1300 includes forming another low-k dielectric liner (e.g., a low-k dielectric liner 208) on the sidewalls of the recess prior to forming the high-k dielectric liner.

In a sixth implementation, alone or in combination with one or more of the first through fifth implementations, a thickness of the high-k dielectric liner is less than a thickness of the low-k dielectric liner, and the thickness of the high-k dielectric liner is greater than a thickness of the other low-k dielectric liner.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

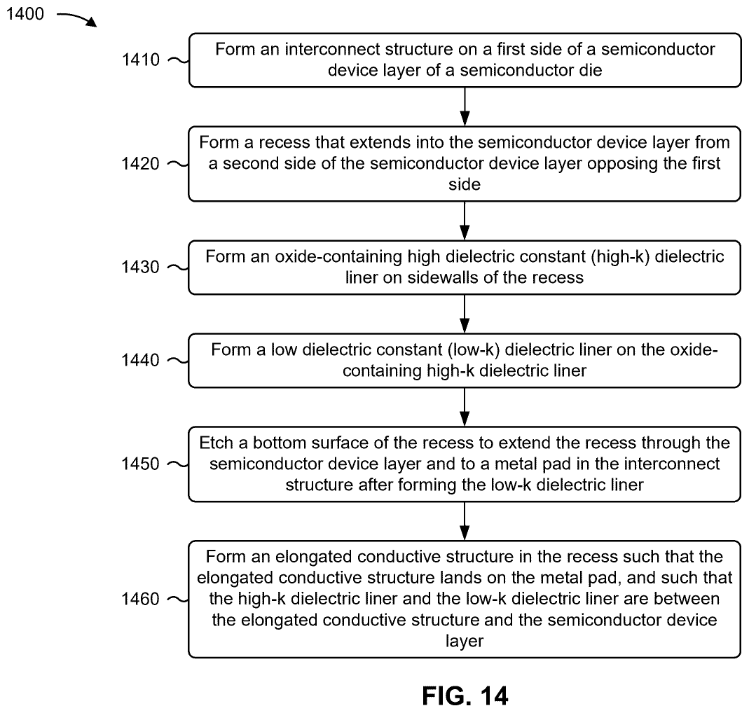

FIG. 14 is a flowchart of an example process 1400 associated with forming a semiconductor die package described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming an interconnect structure on a first side of a semiconductor device layer of a semiconductor die (block 1410). For example, one or more semiconductor processing tools may be used to form an interconnect structure (e.g., an interconnect structure 114) on a first side (e.g., a front side) of a semiconductor device layer (e.g., a semiconductor layer of a device layer 112) of a semiconductor die (e.g., a semiconductor die 104), as described herein.

As further shown in FIG. 14, process 1400 may include forming a recess that extends into the semiconductor device layer from a second side of the semiconductor device layer opposing the first side (block 1420). For example, one or more semiconductor processing tools may be used to form a recess (e.g., a recess 508) that extends into the semiconductor device layer from a second side of the semiconductor device layer opposing the first side, as described herein.

As further shown in FIG. 14, process 1400 may include forming an oxide-containing high-k dielectric liner on sidewalls of the recess (block 1430). For example, one or more semiconductor processing tools may be used to form an oxide-containing high-k dielectric liner (e.g., a high-k dielectric liner 148, a high-k dielectric liner 148a, a high-k dielectric liner 148b, a high-k dielectric liner 148c) on sidewalls of the recess, as described herein.

As further shown in FIG. 14, process 1400 may include forming a low-k dielectric liner on the oxide-containing high-k dielectric liner (block 1440). For example, one or more semiconductor processing tools may be used to form a low-k dielectric liner (e.g., a low-k dielectric liner 150, a low-k dielectric liner 150a, a low-k dielectric liner 150b) on the oxide-containing high-k dielectric liner, as described herein.

As further shown in FIG. 14, process 1400 may include etching a bottom surface of the recess to extend the recess through the semiconductor device layer and to a metal pad in the interconnect structure after forming the low-k dielectric liner (block 1450). For example, one or more semiconductor processing tools may be used to etch a bottom surface of the recess to extend the recess through the semiconductor device layer and to a metal pad (e.g., a conductive structure 128) in the interconnect structure after forming the low-k dielectric liner, as described herein.

As further shown in FIG. 14, process 1400 may include forming an elongated conductive structure in the recess such that the elongated conductive structure lands on the metal pad, and such that the high-k dielectric liner and the low-k dielectric liner are between the elongated conductive structure and the semiconductor device layer (block 1460). For example, one or more semiconductor processing tools may be used to form an elongated conductive structure (e.g., an elongated conductive structure 140) in the recess such that the elongated conductive structure lands on the metal pad, and such that the high-k dielectric liner and the low-k dielectric liner are between the elongated conductive structure and the semiconductor device layer, as described herein.

Process 1400 may include additional implementations, such as any single implementation or any combination of implementations described below and/or in connection with one or more other processes described elsewhere herein.

In a first implementation, etching the bottom surface of the recess includes etching through the oxide-containing high-k dielectric liner and the low-k dielectric liner on the bottom surface of the recess.

In a second implementation, alone or in combination with the first implementation, forming the recess includes forming the recess such that the recess extends partially into an STI region (e.g., an STI region 142) in the semiconductor device layer, where forming the high-k dielectric liner includes forming the high-k dielectric liner on the sidewalls of the recess in the STI region, and where etching the bottom surface of the recess includes etching through the STI region to the metal pad.

In a third implementation, alone or in combination with one or more of the first and second implementations, process 1400 includes forming a low-k dielectric layer (e.g., a low-k buffer layer 502) on the second side of the semiconductor device layer, where forming the recess includes forming a masking layer (e.g., a masking layer 504) on the low-k dielectric layer, forming a pattern (e.g., a pattern 506) in the masking layer, and etching through the low-k dielectric layer and into the semiconductor device layer to form the recess based on the pattern in the masking layer.

In a fourth implementation, alone or in combination with one or more of the first through third implementations, process 1400 includes forming a passivation layer (e.g., a high-k passivation layer 702) on the second side of the semiconductor device layer, and forming a buffer layer (e.g., a low-k passivation layer 704) on the passivation layer, where forming the recess includes forming a masking layer (e.g., a masking layer 504) on the buffer layer, forming a pattern (e.g., a pattern 506) in the masking layer, and etching through the buffer layer and the passivation layer, and into the semiconductor device layer, to form the recess based on the pattern in the masking layer.

In a fifth implementation, alone or in combination with one or more of the first through fourth implementations, the oxide-containing high-k dielectric liner includes at least one of an aluminum oxide (AlₓO_{y}), a tantalum oxide (TaₓO_{y}), a titanium oxide (TiOₓ), a zirconium oxide (ZrOₓ), or a hafnium oxide (HfOₓ).

In a sixth implementation, alone or in combination with one or more of the first through fifth implementations, the oxide-containing high-k dielectric liner includes at least one of a strontium titanium oxide (SrTiOₓ), a hafnium silicon oxide (HfSiOₓ), a lanthanum oxide (LaₓO_{y}), an yttrium oxide (YₓO_{y}), or an amorphous lanthanum aluminum oxide (a-LaAlOₓ).

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, an elongated conductive structure (e.g., a TSV) is included through a device layer of a semiconductor die included in a semiconductor die package. The elongated conductive structure connects to metallization layers in the interconnect structures on opposing sides of the device layer. To prevent, minimize, and/or reduce current leakage from the elongated conductive structure, one or more liners may be included between the elongated conductive structure and the device layer. The one or more liners include a high-k dielectric liner. The high-k dielectric liner provides increased electrical isolation compared to other types of dielectric liners. In this way, the high-k dielectric liner enables increased electrical isolation, in addition to providing surface passivation and/or metal diffusion blocking, to be achieved.

As described in greater detail above, some implementations described herein provide a method. The method includes forming an interconnect structure on a first side of a semiconductor device layer of a semiconductor die. The method includes forming a recess that extends into the semiconductor device layer from a second side of the semiconductor device layer opposing the first side. The method includes forming a high-k dielectric liner on sidewalls of the recess. The method includes forming a low-k dielectric liner on the high-k dielectric liner that is on the sidewalls of the recess. The method includes forming an elongated conductive structure in the recess such that the high-k dielectric liner and the low-k dielectric liner are between the elongated conductive structure and the semiconductor device layer.

As described in greater detail above, some implementations described herein provide a method. The method includes forming an interconnect structure on a first side of a semiconductor device layer of a semiconductor die. The method includes forming a recess that extends into the semiconductor device layer from a second side of the semiconductor device layer opposing the first side. The method includes forming an oxide-containing high-k dielectric liner on sidewalls of the recess. The method includes forming a low-k dielectric liner on the oxide-containing high-k dielectric liner. The method includes etching a bottom surface of the recess to extend the recess through the semiconductor device layer and to a metal pad in the interconnect structure after forming the low-k dielectric liner. The method includes forming an elongated conductive structure in the recess such that the elongated conductive structure lands on the metal pad, and such that the high-k dielectric liner and the low-k dielectric liner are between the elongated conductive structure and the semiconductor device layer.

As described in greater detail above, some implementations described herein provide a semiconductor die package. The semiconductor die package includes a semiconductor device layer. The semiconductor die package includes one or more integrated circuit devices in the semiconductor device layer. The semiconductor die package includes a first interconnect structure vertically adjacent to a first side of the semiconductor device layer. The semiconductor die package includes a second interconnect structure vertically adjacent to a second side of the semiconductor device layer opposing the first side. The semiconductor die package includes an elongated conductive structure extending through the semiconductor device layer between the first side and the second side. The semiconductor die package includes a first metal pad in the first interconnect structure, where the first metal pad is physically coupled with a first end of the elongated conductive structure. The semiconductor die package includes a second metal pad in the second interconnect structure, where the second metal pad is in direct physical contact with a second end of the elongated conductive structure the first end. The semiconductor die package includes an oxide-containing high-k dielectric liner between the elongated conductive structure and the semiconductor device layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an interconnect structure on a first side of a semiconductor device layer of a semiconductor die;
forming a recess that extends into the semiconductor device layer from a second side of the semiconductor device layer opposing the first side;
forming a high dielectric constant (high-k) dielectric liner on sidewalls of the recess;
forming a low dielectric constant (low-k) dielectric liner on the high-k dielectric liner that is on the sidewalls of the recess; and
forming an elongated conductive structure in the recess such that the high-k dielectric liner and the low-k dielectric liner are between the elongated conductive structure and the semiconductor device layer.

2. The method of claim 1, wherein forming the recess comprises:
forming the recess such that a bottom surface of the recess extends into a shallow trench isolation (STI) region in the semiconductor device layer; and
wherein forming the high-k dielectric liner comprises:
forming the high-k dielectric liner on a portion of the sidewalls of the recess in the STI region.

3. The method of claim 1, wherein the high-k dielectric liner comprises an oxide-containing high-k dielectric material.

4. The method of claim 3, further comprising:
forming another high-k dielectric liner on the low-k dielectric liner prior to forming the elongated conductive structure.

5. The method of claim 1, wherein the high-k dielectric liner comprises a high-k dielectric material having a dielectric constant that is greater than a dielectric constant of silicon nitride (SiₓN_{y}).

6. The method of claim 1, further comprising:
forming another low-k dielectric liner on the sidewalls of the recess prior to forming the high-k dielectric liner.

7. The method of claim 6, wherein a thickness of the high-k dielectric liner is less than a thickness of the low-k dielectric liner; and
wherein the thickness of the high-k dielectric liner is greater than a thickness of the other low-k dielectric liner.

8. A method, comprising:
forming an interconnect structure on a first side of a semiconductor device layer of a semiconductor die;
forming a recess that extends into the semiconductor device layer from a second side of the semiconductor device layer opposing the first side;
forming an oxide-containing high dielectric constant (high-k) dielectric liner on sidewalls of the recess;
forming a low dielectric constant (low-k) dielectric liner on the oxide-containing high-k dielectric liner;
etching a bottom surface of the recess to extend the recess through the semiconductor device layer and to a metal pad in the interconnect structure after forming the low-k dielectric liner; and
forming an elongated conductive structure in the recess such that the elongated conductive structure lands on the metal pad, and such that the high-k dielectric liner and the low-k dielectric liner are between the elongated conductive structure and the semiconductor device layer.

9. The method of claim 8, wherein etching the bottom surface of the recess comprises:
etching through the oxide-containing high-k dielectric liner and the low-k dielectric liner on the bottom surface of the recess.

10. The method of claim 8, wherein forming the recess comprises:
forming the recess such that the recess extends partially into a shallow trench isolation (STI) region in the semiconductor device layer;
wherein forming the high-k dielectric liner comprises:
forming the high-k dielectric liner on the sidewalls of the recess in the STI region; and
wherein etching the bottom surface of the recess comprises:
etching through the STI region to the metal pad.

11. The method of claim 8, further comprising:
forming a low-k dielectric layer on the second side of the semiconductor device layer,
wherein forming the recess comprises:
forming a masking layer on the low-k dielectric layer;
forming a pattern in the masking layer; and
etching through the low-k dielectric layer and into the semiconductor device layer to form the recess based on the pattern in the masking layer.

12. The method of claim 8, further comprising:
forming a passivation layer on the second side of the semiconductor device layer; and
forming a buffer layer on the passivation layer,
wherein forming the recess comprises:
forming a masking layer on the buffer layer;
forming a pattern in the masking layer; and
etching through the buffer layer and the passivation layer, and into the semiconductor device layer, to form the recess based on the pattern in the masking layer.

13. The method of claim 8, wherein the oxide-containing high-k dielectric liner comprises at least one of:
an aluminum oxide (AlₓO_{y}),
a tantalum oxide (TaₓO_{y}),
a titanium oxide (TiOₓ),
a zirconium oxide (ZrOₓ), or
a hafnium oxide (HfOₓ).

14. The method of claim 8, wherein the oxide-containing high-k dielectric liner comprises at least one of:
a strontium titanium oxide (SrTiOₓ),
a hafnium silicon oxide (HfSiOₓ),
a lanthanum oxide (LaₓO_{y}),
an yttrium oxide (YₓO_{y}), or
an amorphous lanthanum aluminum oxide (a-LaAlOₓ).

15. A semiconductor package, comprising:
a semiconductor device layer;
one or more integrated circuit devices in the semiconductor device layer;
a first interconnect structure vertically adjacent to a first side of the semiconductor device layer;
a second interconnect structure vertically adjacent to a second side of the semiconductor device layer opposing the first side;
an elongated conductive structure extending through the semiconductor device layer between the first side and the second side;
a first metal pad in the first interconnect structure,
wherein the first metal pad is physically coupled with a first end of the elongated conductive structure;
a second metal pad in the second interconnect structure,
wherein the second metal pad is in direct physical contact with a second end of the elongated conductive structure the first end; and
an oxide-containing high dielectric constant (high-k) dielectric liner between the elongated conductive structure and the semiconductor device layer.

16. The semiconductor package of claim 15, further comprising:
a low dielectric constant (low-k) dielectric liner between the oxide-containing high-k dielectric liner and the elongated conductive structure.

17. The semiconductor package of claim 15, further comprising:
a low dielectric constant (low-k) dielectric liner between the oxide-containing high-k dielectric liner and the semiconductor device layer.

18. The semiconductor package of claim 15, further comprising:
a silicon nitride liner between the oxide-containing high-k dielectric liner and the elongated conductive structure.

19. The semiconductor package of claim 15, wherein the oxide-containing high-k dielectric liner comprises at least one of:
an aluminum oxide (AlₓO_{y}),
a tantalum oxide (TaₓO_{y}),
a titanium oxide (TiOₓ),
a zirconium oxide (ZrOₓ),
a hafnium oxide (HfOₓ),
a strontium titanium oxide (SrTiOₓ),
a hafnium silicon oxide (HfSiOₓ),
a lanthanum oxide (LaₓO_{y}),
an yttrium oxide (YₓO_{y}), or
an amorphous lanthanum aluminum oxide (a-LaAlOₓ).

20. The semiconductor package of claim 15, further comprising:
another oxide-containing high-k dielectric liner between the oxide-containing high-k dielectric liner and the elongated conductive structure,
wherein the oxide-containing high-k dielectric liner comprises a first oxide-containing high-k dielectric material,
wherein the other oxide-containing high-k dielectric liner comprises a second oxide-containing high-k dielectric material, and
wherein the first oxide-containing high-k dielectric material and the second oxide-containing high-k dielectric material are different oxide-containing high-k dielectric materials.
